(19) United States
(12) Patent Application Publication
(10) Pub. No.: US 2026/0331031 A1
(43) Pub. Date: Oct. 22, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: DOYEONG PARK, Yongin-si (KR); DONG HEE SHIN, Yongin-si (KR)

(21) Appl. No.: 19/331,136

(22) Filed: Sep. 17, 2025

(30) Foreign Application Priority Data
Apr. 17, 2025 (KR) 10-2025-0049957

(51) Int. Cl. G09G 3/32; G09G 3/3233

(52) U.S. Cl. CPC G09G 3/32; G09G 3/3233; G09G 2300/0426; G09G 2310/08; G09G 2320/0209; G09G 2320/0233; G09G 2330/021

(57) ABSTRACT

A display device includes pixel circuits disposed in a plurality of pixel rows and a plurality of pixel columns, data lines respectively corresponding to the pixel columns, and light-emitting elements. The pixel circuits include a first pixel circuit disposed in a first pixel row and a first pixel column, a second pixel circuit disposed in the first pixel row and a second pixel column, a third pixel circuit disposed in a second pixel row and the first pixel column, and a fourth pixel circuit disposed in the second pixel row and the second pixel column. A first data line corresponding to the first pixel column is electrically connected to the first and second pixel circuits. A second data line corresponding to the second pixel column is electrically connected to the third and fourth pixel circuits.

### CROSS-REFERENCE TO RELATED APPLICATIONS

This application claims priority under 35 U.S.C. § 119 to Korean Patent Application No. 10-2025-0049957, filed on Apr. 17, 2025, the disclosure of which is hereby incorporated by reference in its entirety.

### TECHNICAL FIELD

Embodiments relate to a display device and an electronic device including the same.

### DISCUSSION OF RELATED ART

A display device is configured to present images, thereby providing visual information to an external viewer, such as a user. With the advancement of information technology, the role of the display device, e.g., as a primary interface between users and digital content, has become increasingly important. Examples of widely used display devices include liquid crystal display (LCD) devices and organic light-emitting diode (OLED) display devices, both of which continue to see growing adoption in various applications.

A display device may include a display area in which images are rendered. Within this display area, a plurality of pixels, each representing the smallest addressable unit of the image, may be arranged. Each pixel may include a pixel circuit configured to drive a light-emitting element, with the light-emitting element generating light in response to signals provided by the pixel circuit.

### SUMMARY

Embodiments provide a display device with improved display quality and reduced power consumption.

Embodiments also provide an electronic device with improved display quality and reduced power consumption.

Additional features of embodiments of the present disclosure will be set forth in the description which follows, and in part will be apparent from the description, or may be learned by practice of embodiments of the present disclosure.

A display device according to an embodiment includes a plurality of pixel circuits disposed in a plurality of pixel rows and a plurality of pixel columns, a plurality of data lines electrically connected to the pixel circuits and respectively corresponding to the pixel columns, and a plurality of light-emitting elements respectively electrically connected to the pixel circuits. The pixel circuits include a first pixel circuit disposed in a first pixel row and a first pixel column, a second pixel circuit disposed in the first pixel row and a second pixel column, a third pixel circuit disposed in a second pixel row and the first pixel column, and a fourth pixel circuit disposed in the second pixel row and the second pixel column. The data lines include a first data line corresponding to the first pixel column and electrically connected to the first pixel circuit and the second pixel circuit, and a second data line corresponding to the second pixel column and electrically connected to the third pixel circuit and the fourth pixel circuit.

In an embodiment, the first data line may overlap the first pixel circuit and the third pixel circuit in a plan view, and may be electrically insulated from the third pixel circuit. The second data line may overlap the second pixel circuit and the fourth pixel circuit in the plan view, and may be electrically insulated from the second pixel circuit.

In an embodiment, light-emitting elements that emit light of the same color may be respectively electrically connected to all of the pixel circuits electrically connected to the second data line.

In an embodiment, in a plan view, the first pixel circuit and the second pixel circuit may have the same shape as each other, the third pixel circuit and the fourth pixel circuit may have the same shape as each other, the first pixel circuit and the third pixel circuit may have shapes that are symmetrical to each other along a column direction, and the second pixel circuit and the fourth pixel circuit may have shapes that are symmetrical to each other along the column direction.

In an embodiment, the light-emitting elements may be disposed in the pixel rows and the pixel columns. The light-emitting elements may include a first light-emitting element electrically connected to the first pixel circuit and disposed in the first pixel row and the first pixel column, a second light-emitting element electrically connected to the second pixel circuit and disposed in the second pixel row and the first pixel column, a third light-emitting element electrically connected to the third pixel circuit and disposed in the first pixel row and the second pixel column, and a fourth light-emitting element electrically connected to the fourth pixel circuit and disposed in the second pixel row and the second pixel column.

In an embodiment, the first light-emitting element may emit red light, the second light-emitting element may emit blue light, and the third light-emitting element and the fourth light-emitting element may emit green light.

In an embodiment, the pixel circuits may further include a fifth pixel circuit disposed in the first pixel row and a third pixel column, a sixth pixel circuit disposed in the first pixel row and a fourth pixel column, a seventh pixel circuit disposed in the second pixel row and the third pixel column, and an eighth pixel circuit disposed in the second pixel row and the fourth pixel column. The data lines may further include a third data line corresponding to the third pixel column and electrically connected to the fifth pixel circuit and the sixth pixel circuit, and a fourth data line corresponding to the fourth pixel column and electrically connected to the seventh pixel circuit and the eighth pixel circuit.

In an embodiment, the light-emitting elements may include a fifth light-emitting element electrically connected to the fifth pixel circuit and disposed in the first pixel row and the third pixel column, a sixth light-emitting element electrically connected to the sixth pixel circuit and disposed in the second pixel row and the third pixel column, a seventh light-emitting element electrically connected to the seventh pixel circuit and disposed in the first pixel row and the fourth pixel column, and an eighth light-emitting element electrically connected to the eighth pixel circuit and disposed in the second pixel row and the fourth pixel column.

In an embodiment, the fifth light-emitting element may emit blue light, the sixth light-emitting element may emit red light, and the seventh light-emitting element and the eighth light-emitting element may emit green light.

In an embodiment, in a plan view, the first pixel circuit and the sixth pixel circuit may have the same shape as each other, and the second pixel circuit and the fifth pixel circuit may have the same shape as each other.

In an embodiment, each of the pixel circuits may include a driving transistor and a write transistor electrically connected to a gate electrode of the driving transistor. The first data line may be electrically connected to a drain electrode of a first write transistor of the first pixel circuit and a drain electrode of a second write transistor of the second pixel circuit. The second data line may be electrically connected to a drain electrode of a third write transistor of the third pixel circuit and a drain electrode of a fourth write transistor of the fourth pixel circuit.

In an embodiment, the display device may further include a first data connection line disposed in the first pixel row, extending in a row direction, and electrically connecting the first data line, the drain electrode of the first write transistor, and the drain electrode of the second write transistor, and a second data connection line disposed in the second pixel row, extending in the row direction, and electrically connecting the second data line, the drain electrode of the third write transistor, and the drain electrode of the fourth write transistor.

In an embodiment, the display device may further include a first data connection pattern overlapping the first data line and the first data connection line in a plan view, a second data connection pattern overlapping the second data line and the first data connection line in the plan view, a third data connection pattern overlapping the first data line and the second data connection line in the plan view, and a fourth data connection pattern overlapping the second data line and the second data connection line in the plan view. The first data line may contact the first data connection line through a first contact hole, and may be electrically insulated from the second data connection line. The second data line may contact the second data connection line through a second contact hole, and may be electrically insulated from the first data connection line.

In an embodiment, in the plan view, the first data connection pattern and the second data connection pattern may have the same shape as each other, the third data connection pattern and the fourth data connection pattern may have the same shape as each other, the first data connection pattern and the third data connection pattern may have shapes that are symmetrical to each other along a column direction, and the second data connection pattern and the fourth data connection pattern may have shapes that are symmetrical to each other along the column direction.

In an embodiment, the display device may further include a plurality of write gate lines electrically connected to the pixel circuits and respectively corresponding to the pixel rows. The write gate lines may include a first write gate line corresponding to the first pixel row and electrically connected to the first pixel circuit and the third pixel circuit, and a second write gate line corresponding to the second pixel row and electrically connected to the second pixel circuit and the fourth pixel circuit.

In an embodiment, the first write gate line may overlap the first pixel circuit and the second pixel circuit in a plan view, and may be electrically insulated from the second pixel circuit. The second write gate line may overlap the third pixel circuit and the fourth pixel circuit in the plan view and may be electrically insulated from the third pixel circuit.

In an embodiment, the display device may further include a first gate connection line disposed in the first pixel column, extending in a column direction, electrically connected to the first write gate line, and including a gate electrode of the first write transistor and a gate electrode of the third write transistor, and a second gate connection line disposed in the second pixel column, extending in the column direction, electrically connected to the second write gate line, and including a gate electrode of the second write transistor and a gate electrode of the fourth write transistor.

In an embodiment, the first gate connection line may overlap the first write gate line and the second write gate line in a plan view, may contact the first write gate line through a third contact hole, and may be electrically insulated from the second write gate line. The second gate connection line may overlap the first write gate line and the second write gate line in the plan view, may contact the second write gate line through a fourth contact hole, and may be electrically insulated from the first write gate line.

In an embodiment, the write gate lines may further include a third write gate line corresponding to a third pixel row, and a fourth write gate line corresponding to a fourth pixel row. An on-period of a first write gate signal applied to the first write gate line may not overlap an on-period of a second write gate signal applied to the second write gate line. The on-period of the first write gate signal may partially overlap an on-period of a third write gate signal applied to the third write gate line or an on-period of a fourth write gate signal applied to the fourth write gate line.

An electronic device according to an embodiment includes a display device configured to display an image and a processor configured to transmit input image data and an input control signal to the display device. The display device includes a plurality of pixel circuits disposed in a plurality of pixel rows and a plurality of pixel columns, a plurality of data lines electrically connected to the pixel circuits and respectively corresponding to the pixel columns, and a plurality of light-emitting elements respectively electrically connected to the pixel circuits. The pixel circuits include a first pixel circuit disposed in a first pixel row and a first pixel column, a second pixel circuit disposed in the first pixel row and a second pixel column, a third pixel circuit disposed in a second pixel row and the first pixel column, and a fourth pixel circuit disposed in the second pixel row and the second pixel column. The data lines include a first data line corresponding to the first pixel column and electrically connected to the first pixel circuit and the second pixel circuit, and a second data line corresponding to the second pixel column and electrically connected to the third pixel circuit and the fourth pixel circuit.

According to embodiments, the display quality of the display device may be improved, and the power consumption of the display device may be reduced.

### BRIEF DESCRIPTION OF THE DRAWINGS

The above and other features of the present disclosure will become more apparent by describing in detail embodiments thereof with reference to the accompanying drawings.

FIG. 1 is a block diagram illustrating a display device according to an embodiment.

FIG. 2 is a schematic diagram illustrating an arrangement of pixels according to an embodiment.

FIG. 3 is an equivalent circuit diagram schematically illustrating a pixel according to an embodiment.

FIG. 4 is a cross-sectional view illustrating a display panel according to an embodiment.

FIGS. 5 to 19 are layout views illustrating a pixel according to an embodiment.

FIGS. 20 and 21 are plan views illustrating first to eighth pixels according to an embodiment.

FIG. 22 is an enlarged plan view illustrating area A of FIG. 20.

FIGS. 23 to 25 are timing diagrams of write gate signals according to embodiments.

FIG. 26 is a block diagram illustrating an electronic device according to an embodiment.

FIG. 27 is a schematic diagram illustrating electronic devices according to various embodiments.

### DETAILED DESCRIPTION

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

As used herein, the singular forms “a,” “an” and “the” are intended to include the plural forms as well, unless the context clearly indicates otherwise.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In embodiments described herein, a display device is provided that may achieve improved image quality and reduced power consumption through a novel pixel circuit configuration and drive method. The pixel circuit includes a driving transistor having a back gate electrode and cooperating capacitors configured to store both threshold voltage information and data voltage, enabling precise control of the driving current supplied to the light-emitting element. The arrangement of emission control transistors, initialization transistors, and reference voltage application paths may allow the device to effectively mitigate variations in threshold voltage and to suppress artifacts such as, e.g., luminance non-uniformity, crosstalk, and low gray-level staining.

Further, embodiments implement a layout in which pixel circuits associated with light-emitting elements of the same color have the same physical shape in plan view, or shapes that are symmetrical along a pixel row direction. This arrangement may promote uniform electrical characteristics among pixels of the same color, reducing color shift and luminance deviation while enabling higher resolution through efficient use of pixel area. Additionally, by controlling the connections between data lines and write gate lines such that pixels of the same color share certain drive lines while remaining individually addressable, the display device according to embodiments may reduce unnecessary signal transitions, thereby lowering overall power consumption.

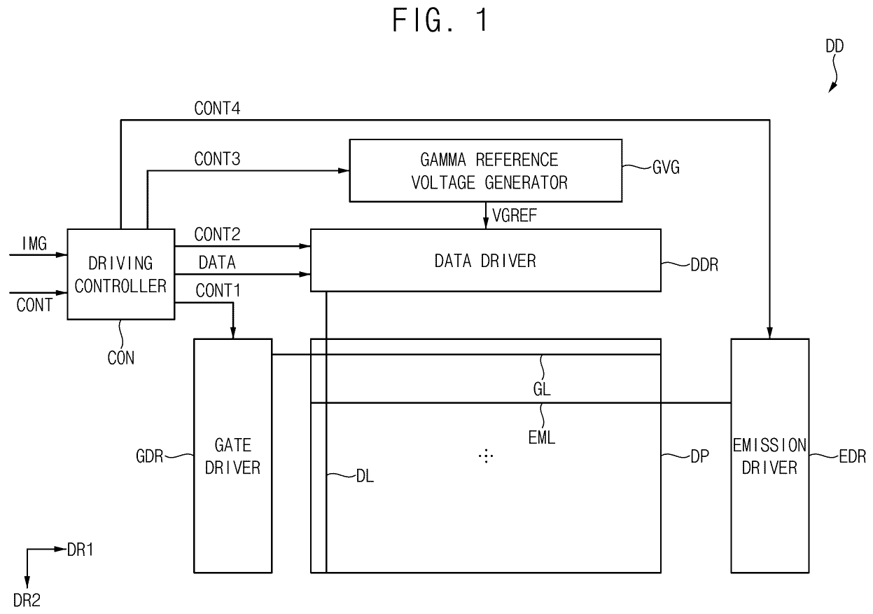

FIG. 1 is a block diagram illustrating a display device according to an embodiment.

Referring to FIG. 1, a display device DD according to an embodiment may include a display panel DP and a panel driver for driving the display panel DP. The panel driver may include a driving controller CON, a gate driver GDR, a gamma reference voltage generator GVG, a data driver DDR, and an emission driver EDR.

In an embodiment, the driving controller CON and the data driver DDR may be integrated. In an embodiment, the driving controller CON, the gamma reference voltage generator GVG, and the data driver DDR may be integrated. In an embodiment, the driving controller CON, the gate driver GDR, the gamma reference voltage generator GVG, and the data driver DDR may be integrated. For example, a driving module which is provided by (e.g., formed by) an integration of at least the driving controller CON and the data driver DDR may be referred to as a timing controller embedded data driver (TED). In an embodiment, the gate driver GDR and the emission driver EDR may be integrated.

The display panel DP may include a display area for displaying an image and a peripheral area positioned outside the display area.

The display panel DP may include a plurality of gate lines GL, a plurality of data lines DL, a plurality of emission control lines EML, and a plurality of pixels. The plurality of pixels may be disposed in the display area, and may be electrically connected to the plurality of gate lines GL, the plurality of data lines DL, and the plurality of emission control lines EML. In an embodiment, the gate lines GL may include write gate lines that transmit write gate signals, reference gate lines that transmit reference gate signals, and initialization gate lines that transmit initialization gate signals. In an embodiment, the emission control lines EML may include first emission control lines that transmit first emission control signals and second emission control lines that transmit second emission control signals.

In an embodiment, each of the gate lines GL and the emission control lines EML may extend generally in a first direction D1. Each of the data lines DL may extend generally in a second direction D2 crossing the first direction D1.

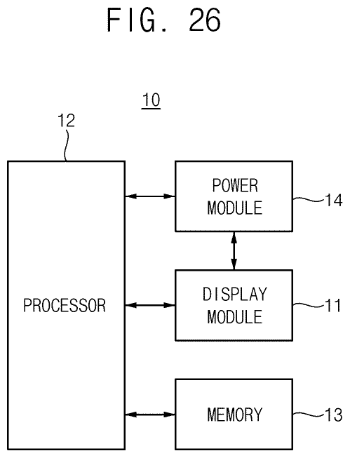

The driving controller CON may receive input image data IMG and an input control signal CONT from an external host processor (e.g., a processor 12 of FIG. 26). For example, the input image data IMG may include red image data, green image data, and blue image data. For example, the input image data IMG may further include white image data. For example, the input image data IMG may include magenta image data, yellow image data, cyan image data, or the like. The input control signal CONT may include a master clock signal and a data enable signal. The input control signal CONT may further include a vertical synchronization signal and a horizontal synchronization signal.

The driving controller CON may generate a first control signal CONT1, a second control signal CONT2, a third control signal CONT3, a fourth control signal CONT4, and a data signal DATA based on the input image data IMG and the input control signal CONT.

The driving controller CON may generate the first control signal CONT1 for controlling the operation of the gate driver GDR based on the input control signal CONT. The driving controller CON may output the first control signal CONT1 to the gate driver GDR. The first control signal CONT1 may include a vertical start signal and a scan clock signal.

The driving controller CON may generate the second control signal CONT2 for controlling the operation of the data driver DDR based on the input control signal CONT. The driving controller CON may output the second control signal CONT2 to the data driver DDR. The second control signal CONT2 may include a horizontal start signal and a load signal.

The driving controller CON may generate the data signal DATA based on the input image data IMG. The driving controller CON may output the data signal DATA to the data driver DDR.

The driving controller CON may generate the third control signal CONT3 for controlling the operation of the gamma reference voltage generator GVG based on the input control signal CONT. The driving controller CON may output the third control signal CONT3 to the gamma reference voltage generator GVG.

The driving controller CON may generate the fourth control signal CONT4 for controlling the operation of the emission driver EDR based on the input control signal CONT. The driving controller CON may output the fourth control signal CONT4 to the emission driver EDR.

The gate driver GDR may generate gate signals in response to the first control signal CONT1 received from the driving controller CON. The gate driver GDR may output the gate signals to the gate lines GL. In an embodiment, the gate driver GDR may be integrated or mounted on the peripheral area of the display panel DP.

The gamma reference voltage generator GVG may generate a gamma reference voltage VGREF in response to the third control signal CONT3 received from the driving controller CON. The gamma reference voltage generator GVG may provide the gamma reference voltage VGREF to the data driver DDR. The gamma reference voltage VGREF may have a value corresponding to each data signal DATA.

In an embodiment, the gamma reference voltage generator GVG may be disposed in the driving controller CON or in the data driver DDR.

The data driver DDR may receive the second control signal CONT2 and the data signal DATA from the driving controller CON, and may receive the gamma reference voltage VGREF from the gamma reference voltage generator GVG. The data driver DDR may convert the data signal DATA into a data voltage in analog form using the gamma reference voltage VGREF. The data driver DDR may output the data voltage to the data lines DL.

The emission driver EDR may generate emission control signals in response to the fourth control signal CONT4 received from the driving controller CON. The emission driver EDR may output the emission control signals to the emission control lines EML.

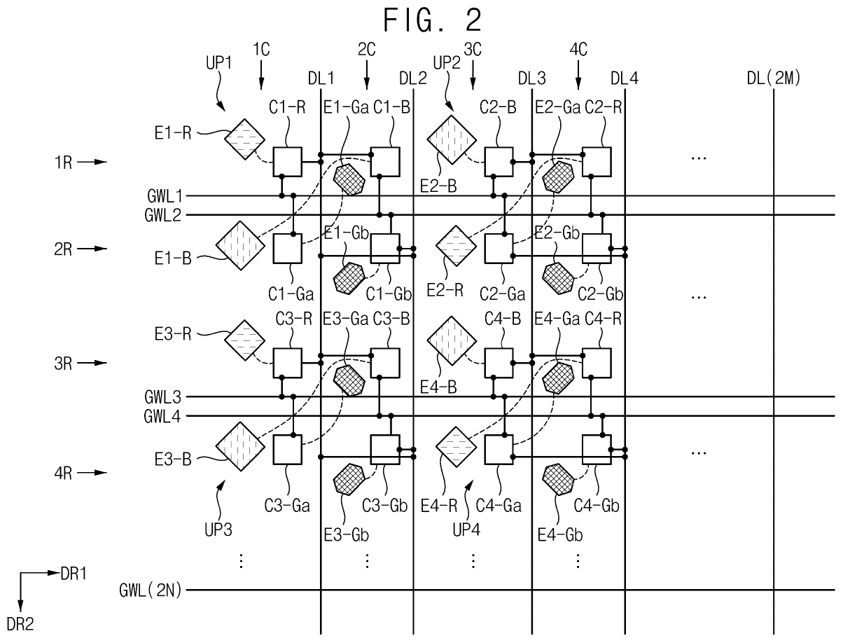

FIG. 2 is a schematic diagram illustrating an arrangement of pixels according to an embodiment.

FIG. 2 schematically illustrates the arrangement of the pixels, the data lines DL and the write gate lines GWL included in the display panel DP of FIG. 1 according to an embodiment.

Referring to FIGS. 1 and 2, in an embodiment, the display panel DP may include the write gate lines GWL1 to GWL(2N), the data lines DL1 to DL(2M), and the pixels. Each of the pixels may include a pixel circuit and a light-emitting element electrically connected to the pixel circuit. The pixel circuit may include at least one thin-film transistor and at least one capacitor. The light-emitting element may emit light based on a driving current provided from the pixel circuit. The light-emitting element may include an organic light-emitting element, an inorganic light-emitting element, a quantum dot light emitting diode, a micro light emitting diode, or the like.

The pixel circuits may be electrically connected to the gate lines GL, the data lines DL, and the emission control lines EML. In an embodiment, the pixel circuits may be disposed in a plurality of pixel rows and a plurality of pixel columns in the display area. Each of the pixel rows may extend in the first direction DR1, and each of the pixel columns may extend in the second direction DR2. For example, the second direction DR2 may be perpendicular to the first direction DR1. Hereinafter, the first direction DR1 may be referred to as a row direction, and the second direction DR2 may be referred to as a column direction.

In an embodiment, 2N pixel rows and 2M pixel columns may be defined on the display panel DP (N and M are positive integers greater than or equal to 2). First to 2N-th pixel rows may be disposed in the second direction DR2, and first to 2M-th pixel columns may be disposed along in first direction DR1.

For convenience of description, FIG. 2 illustrates 16 pixel circuits disposed in the first to fourth pixel rows 1R to 4R and the first to fourth pixel columns 1C to 4C among the pixel circuits. Hereinafter, first to sixteenth pixel circuits illustrated in FIG. 2 and the write gate lines, the data lines, and the light-emitting elements connected to the first to sixteenth pixel circuits will be described in detail.

The first pixel circuit C1-R may be disposed in the first pixel row 1R and the first pixel column 1C. The second pixel circuit C1-B may be disposed in the first pixel row 1R and the second pixel column 2C. The third pixel circuit C1-Ga may be disposed in the second pixel row 2R and the first pixel column 1C. The fourth pixel circuit C1-Gb may be disposed in the second pixel row 2R and the second pixel column 2C. The fifth pixel circuit C2-B may be disposed in the first pixel row 1R and the third pixel column 3C. The sixth pixel circuit C2-R may be disposed in the first pixel row 1R and the fourth pixel column 4C. The seventh pixel circuit C2-Ga may be disposed in the second pixel row 2R and the third pixel column 3C. The eighth pixel circuit C2-Gb may be disposed in the second pixel row 2R and the fourth pixel column 4C. The ninth pixel circuit C3-R may be disposed in the third pixel row 3R and the first pixel column 1C. The tenth pixel circuit C3-B may be disposed in the third pixel row 3R and the second pixel column 2C. The eleventh pixel circuit C3-Ga may be disposed in the fourth pixel row 4R and the first pixel column 1C. The twelfth pixel circuit C3-Gb may be disposed in the fourth pixel row 4R and the second pixel column 2C. The thirteenth pixel circuit C4-B may be disposed in the third pixel row 3R and the third pixel column 3C. The fourteenth pixel circuit C4-R may be disposed in the third pixel row 3R and the fourth pixel column 4C. The fifteenth pixel circuit C4-Ga may be disposed in the fourth pixel row 4R and the third pixel column 3C. The sixteenth pixel circuit C4-Gb may be disposed in the fourth pixel row 4R and the fourth pixel column 4C.

In an embodiment, in a plan view, some of the pixel circuits disposed in the same pixel row may have the same shape as each other. For example, in a plan view, the first pixel circuit C1-R, the second pixel circuit C1-B, the fifth pixel circuit C2-B, and the sixth pixel circuit C2-R, which are disposed in the first pixel row 1R, may have the same shape as each other. In a plan view, the third pixel circuit C1-Ga, the fourth pixel circuit C1-Gb, the seventh pixel circuit C2-Ga, and the eighth pixel circuit C2-Gb, which are disposed in the second pixel row 2R, may have the same shape as each other. In a plan view, the ninth pixel circuit C3-R, the tenth pixel circuit C3-B, the thirteenth pixel circuit C4-B, and the fourteenth pixel circuit C4-R, which are disposed in the third pixel row 3R, may have the same shape as each other. In a plan view, the eleventh pixel circuit C3-Ga, the twelfth pixel circuit C3-Gb, the fifteenth pixel circuit C4-Ga, and the sixteenth pixel circuit C4-Gb, which are disposed in the fourth pixel row 4R, may have the same shape as each other.

In some embodiments, arranging pixel circuits of the same row to have identical shapes may also improve manufacturability. The repetitive pattern within a row can simplify mask design for lithographic processes, thereby reducing alignment complexity and improving yield. This regularity in circuit geometry can also facilitate predictable electrical characteristics along a row, which may complement the selective data line and write gate line connections described below.

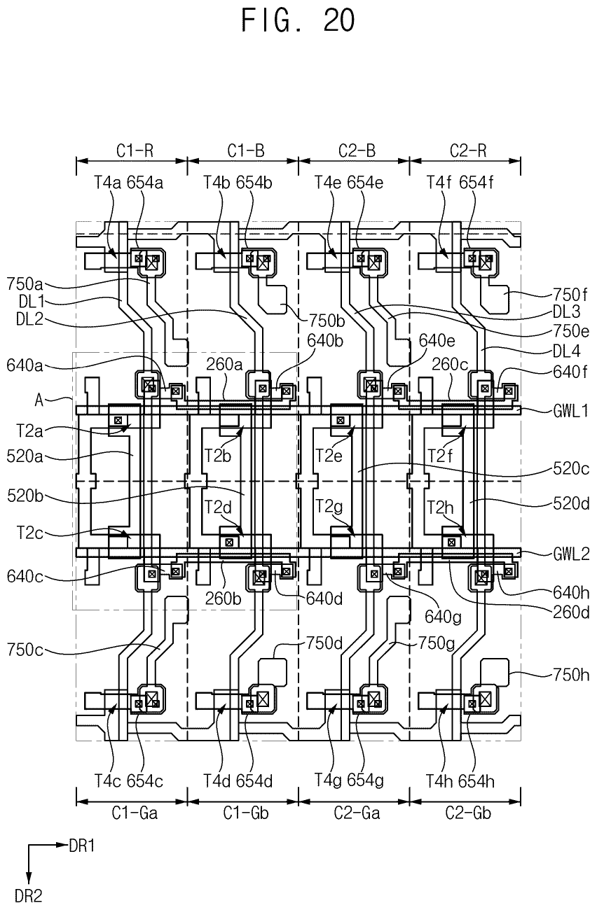

In an embodiment, in a plan view, some of the pixel circuits respectively disposed in two adjacent pixel rows may have shapes that are symmetrical to each other along the second direction DR2. For example, in a plan view, the first pixel circuit C1-R, the second pixel circuit C1-B, the fifth pixel circuit C2-B, and the sixth pixel circuit C2-R, which are disposed in the first pixel row 1R, may have shapes that are respectively symmetrical to shapes of the third pixel circuit C1-Ga, the fourth pixel circuit C1-Gb, the seventh pixel circuit C2-Ga, and the eighth pixel circuit C2-Gb, which are disposed in the second pixel row 2R adjacent to the first pixel row 1R, along the second direction DR2. In a plan view, the ninth pixel circuit C3-R, the tenth pixel circuit C3-B, the thirteenth pixel circuit C4-B, and the fourteenth pixel circuit C4-R, which are disposed in the third pixel row 3R, may have shapes that are respectively symmetrical to shapes of the eleventh pixel circuit C3-Ga, the twelfth pixel circuit C3-Gb, the fifteenth pixel circuit C4-Ga, and the sixteenth pixel circuit C4-Gb, which are disposed in the fourth pixel row 4R adjacent to the third pixel row 3R, along the second direction DR2. This will be described later with reference to FIG. 20.

In some embodiments, arranging pixel circuits with symmetrical shapes in adjacent rows along the second direction DR2 may also simplify routing of the write gate lines GWL and data lines DL. By maintaining predictable and repetitive symmetry in circuit geometry, line routing congestion can be reduced, which can facilitate more consistent parasitic capacitance across adjacent pixel circuits. This consistency may contribute to stable signal transmission when the same data voltage is applied to pixel circuits of the same color in different rows, thereby helping maintain uniform luminance across the display panel DP.

The write gate lines GWL1 to GWL(2N) may each extend in the first direction DR1, and may be spaced apart from each other in the second direction DR2. In an embodiment, the write gate lines GWL1 to GWL(2N) may be disposed to respectively correspond to the pixel rows. As illustrated in FIG. 2, the first write gate line GWL1 may be disposed to correspond to the first pixel row 1R, the second write gate line GWL2 may be disposed to correspond to the second pixel row 2R, the third write gate line GWL3 may be disposed to correspond to the third pixel row 3R, the fourth write gate line GWL4 may be disposed to correspond to the fourth pixel row 4R, and the 2N-th write gate line GWL(2N) may be disposed to correspond to the 2N-th pixel row.

In an embodiment, each of the write gate lines GWL1 to GWL(2N) may be electrically connected to some of the pixel circuits disposed in the corresponding pixel row, and may be electrically disconnected to (or electrically insulated from) the remaining pixel circuits. In addition, each of the write gate lines GWL1 to GWL(2N) may be electrically connected to some of the pixel circuits disposed in an adjacent pixel row adjacent to the corresponding pixel row, and may be electrically disconnected to (or electrically insulated from) the remaining pixel circuits.

In an embodiment, as illustrated in FIG. 2, the first write gate line GWL1 disposed to correspond to the first pixel row 1R may be electrically connected to the first pixel circuit C1-R and the fifth pixel circuit C2-B among the pixel circuits disposed in the first pixel row 1R, and may be electrically disconnected to (or electrically insulated from) the second pixel circuit C1-B and the sixth pixel circuit C2-R among the pixel circuits disposed in the first pixel row 1R. The first write gate line GWL1 disposed to correspond to the first pixel row 1R may be electrically connected to the third pixel circuit C1-Ga and the seventh pixel circuit C2-Ga among the pixel circuits disposed in the second pixel row 2R, and may be electrically disconnected to (or electrically insulated from) the fourth pixel circuit C1-Gb and the eighth pixel circuit C2-Gb among the pixel circuits disposed in the second pixel row 2R.

The first write gate line GWL1 may provide the write gate signals to the first pixel circuit C1-R, the third pixel circuit C1-Ga, the fifth pixel circuit C2-B, and the seventh pixel circuit C2-Ga.

The second write gate line GWL2 disposed to correspond to the second pixel row 2R may be electrically connected to the second pixel circuit C1-B and the sixth pixel circuit C2-R among the pixel circuits disposed in the first pixel row 1R, and may be electrically disconnected to (or electrically insulated from) the first pixel circuit C1-R and the fifth pixel circuit C2-B among the pixel circuits disposed in the first pixel row 1R. The second write gate line GWL2 disposed to correspond to the second pixel row 2R may be electrically connected to the fourth pixel circuit C1-Gb and the eighth pixel circuit C2-Gb among the pixel circuits disposed in the second pixel row 2R, and may be electrically disconnected to (or electrically insulated from) the third pixel circuit C1-Ga and the seventh pixel circuit C2-Ga among the pixel circuits disposed in the second pixel row 2R.

The second write gate line GWL2 may provide the write gate signals to the second pixel circuit C1-B, the fourth pixel circuit C1-Gb, the sixth pixel circuit C2-R, and the eighth pixel circuit C2-Gb.

The third write gate line GWL3 disposed to correspond to the third pixel row 3R may be electrically connected to the ninth pixel circuit C3-R and the thirteenth pixel circuit C4-B among the pixel circuits disposed in the third pixel row 3R, and may be electrically disconnected to (or electrically insulated from) the tenth pixel circuit C3-B and the fourteenth pixel circuit C4-R among the pixel circuits disposed in the third pixel row 3R. The third write gate line GWL3 disposed to correspond to the third pixel row 3R may be electrically connected to the eleventh pixel circuit C3-Ga and the fifteenth pixel circuit C4-Ga among the pixel circuits disposed in the fourth pixel row 4R, and may be electrically disconnected to (or electrically insulated from) the twelfth pixel circuit C3-Gb and the sixteenth pixel circuit C4-Gb among the pixel circuits disposed in the fourth pixel row 4R.

The third write gate line GWL3 may provide the write gate signals to the ninth pixel circuit C3-R, the eleventh pixel circuit C3-Ga, the thirteenth pixel circuit C4-B, and the fifteenth pixel circuit C4-Ga.

The fourth write gate line GWL4 disposed to correspond to the fourth pixel row 4R may be electrically connected to the tenth pixel circuit C3-B and the fourteenth pixel circuit C4-R among the pixel circuits disposed in the third pixel row 3R, and may be electrically disconnected to (or electrically insulated from) the ninth pixel circuit C3-R and the thirteenth pixel circuit C4-B among the pixel circuits disposed in the third pixel row 3R. The fourth write gate line GWL4 disposed to correspond to the fourth pixel row 4R may be electrically connected to the twelfth pixel circuit C3-Gb and the sixteenth pixel circuit C4-Gb among the pixel circuits disposed in the fourth pixel row 4R, and may be electrically disconnected to (or electrically insulated from) the eleventh pixel circuit C3-Ga and the fifteenth pixel circuit C4-Ga among the pixel circuits disposed in the fourth pixel row 4R.

The fourth write gate line GWL4 may provide the write gate signals to the tenth pixel circuit C3-B, the twelfth pixel circuit C3-Gb, the fourteenth pixel circuit C4-R, and the sixteenth pixel circuit C4-Gb.

The data lines DL1 to DL(2M) may each extend in the second direction DR2, and may be spaced apart from each other in the first direction DR1. In an embodiment, the data lines DL1 to DL(2M) may be disposed to respectively correspond to the pixel columns. As illustrated in FIG. 2, the first data line DL 1 may be disposed to correspond to the first pixel column 1C, the second data line DL 2 may be disposed to correspond to the second pixel column 2C, the third data line DL3 may be disposed to correspond to the third pixel column 3C, the fourth data line DL 4 may be disposed to correspond to the fourth pixel column 4C, and the 2M-th data line DL(2M) may be disposed to correspond to the 2M-th pixel column.

In an embodiment, each of the data lines DL1 to DL(2M) may be electrically connected to some of the pixel circuits disposed in the corresponding pixel column, and may be electrically disconnected to (or electrically insulated from) the remaining pixel circuits. In addition, each of the data lines DL1 to DL(2M) may be electrically connected to some of the pixel circuits disposed in an adjacent pixel column adjacent to the corresponding pixel column, and may be electrically disconnected to (or electrically insulated from) the remaining pixel circuits.

In an embodiment, as illustrated in FIG. 2, the first data line DL1 disposed to correspond to the first pixel column 1C may be electrically connected to the first pixel circuit C1-R and the ninth pixel circuit C3-R among the pixel circuits disposed in the first pixel column 1C, and may be electrically disconnected to (or electrically insulated from) the third pixel circuit C1-Ga and the eleventh pixel circuit C3-Ga among the pixel circuits disposed in the first pixel column 1C. The first data line DL1 disposed to correspond to the first pixel column 1C may be electrically connected to the second pixel circuit C1-B and the tenth pixel circuit C3-B among the pixel circuits disposed in the second pixel column 2C, and may be electrically disconnected to (or electrically insulated from) the fourth pixel circuit C1-Gb and the twelfth pixel circuit C3-Gb among the pixel circuits disposed in the second pixel column 2C.

The first data line DL1 may provide the data voltages to the first pixel circuit C1-R, the second pixel circuit C1-B, the ninth pixel circuit C3-R, and the tenth pixel circuit C3-B.

The second data line DL 2 disposed to correspond to the second pixel column 2C may be electrically connected to the third pixel circuit C1-Ga and the eleventh pixel circuit C3-Ga among the pixel circuits disposed in the first pixel column 1C, and may be electrically disconnected to (or electrically insulated from) the first pixel circuit C1-R and the ninth pixel circuit C3-R among the pixel circuits disposed in the first pixel column 1C. The second data line DL 2 disposed to correspond to the second pixel column 2C may be electrically connected to the fourth pixel circuit C1-Gb and the twelfth pixel circuit C3-Gb among the pixel circuits disposed in the second pixel column 2C, and may be electrically disconnected to (or electrically insulated from) the second pixel circuit C1-B and the tenth pixel circuit C3-B among the pixel circuits disposed in the second pixel column 2C.

The second data line DL2 may provide the data voltages to the third pixel circuit C1-Ga, the fourth pixel circuit C1-Gb, the eleventh pixel circuit C3-Ga, and the twelfth pixel circuit C3-Gb.

The third data line DL3 disposed to correspond to the third pixel column 3C may be electrically connected to the fifth pixel circuit C2-B and the thirteenth pixel circuit C4-B among the pixel circuits disposed in the third pixel column 3C, and may be electrically disconnected to (or electrically insulated from) the seventh pixel circuit C2-Ga and the fifteenth pixel circuit C4-Ga among the pixel circuits disposed in the third pixel column 3C. The third data line DL3 disposed to correspond to the third pixel column 3C may be electrically connected to the sixth pixel circuit C2-R and the fourteenth pixel circuit C4-R among the pixel circuits disposed in the fourth pixel column 4C, and may be electrically disconnected to (or electrically insulated from) the eighth pixel circuit C2-Gb and the sixteenth pixel circuit C4-Gb among the pixel circuits disposed in the fourth pixel column 4C.

The third data line DL3 may provide the data voltages to the fifth pixel circuit C2-B, the sixth pixel circuit C2-R, the thirteenth pixel circuit C4-B, and the fourteenth pixel circuit C4-R.

The fourth data line DL 4 disposed to correspond to the fourth pixel column 4C may be electrically connected to the seventh pixel circuit C2-Ga and the fifteenth pixel circuit C4-Ga among the pixel circuits disposed in the third pixel column 3C, and may be electrically disconnected to (or electrically insulated from) the fifth pixel circuit C2-B and the thirteenth pixel circuit C4-B among the pixel circuits disposed in the third pixel column 3C. The fourth data line DL 4 disposed to correspond to the fourth pixel column 4C may be electrically connected to the eighth pixel circuit C2-Gb and the sixteenth pixel circuit C4-Gb among the pixel circuits disposed in the fourth pixel column 4C, and may be electrically disconnected to (or electrically insulated from) the sixth pixel circuit C2-R and the fourteenth pixel circuit C4-R among the pixel circuits disposed in the fourth pixel column 4C.

The fourth data line DL4 may provide data voltages to the seventh pixel circuit C2-Ga, the eighth pixel circuit C2-Gb, the fifteenth pixel circuit C4-Ga, and the sixteenth pixel circuit C4-Gb.

In an embodiment, assigning specific data lines DL to selectively drive only pixel circuits of a single color, as shown in FIG. 2, may reduce the peak instantaneous current demand from the data driver circuitry. Because only a subset of pixel circuits is addressed by a given data line during a refresh cycle, the load on the corresponding data driver can be reduced, which may enable the use of lower-capacity or lower-power driver circuits. Such an arrangement can also mitigate signal delay and voltage drop along the data lines DL, including in high-resolution displays where line lengths are increased.

One light-emitting element may be electrically connected to each of the pixel circuits. In an embodiment, the light-emitting elements electrically connected to the pixel circuits may be disposed in the pixel rows and the pixel columns in the display area. In an embodiment, some of the light-emitting elements may be disposed in different pixel rows and/or different pixel columns from the corresponding pixel circuits.

In an embodiment, as illustrated in FIG. 2, a first light-emitting element E1-R electrically connected to the first pixel circuit C1-R may be disposed in the first pixel row 1R and the first pixel column 1C. A second light-emitting element E1-B electrically connected to the second pixel circuit C1-B may be disposed in the second pixel row 2R and the first pixel column 1C. A third light-emitting element E1-Ga electrically connected to the third pixel circuit C1-Ga may be disposed in the first pixel row 1R and the second pixel column 2C. A fourth light-emitting element E1-Gb electrically connected to the fourth pixel circuit C1-Gb may be disposed in the second pixel row 2R and the second pixel column 2C. A fifth light-emitting element E2-B electrically connected to the fifth pixel circuit C2-B may be disposed in the first pixel row 1R and the third pixel column 3C. A sixth light-emitting element E2-R electrically connected to the sixth pixel circuit C2-R may be disposed in the second pixel row 2R and the third pixel column 3C. A seventh light-emitting element E2-Ga electrically connected to the seventh pixel circuit C2-Ga may be disposed in the first pixel row 1R and the fourth pixel column 4C. An eighth light-emitting element E2-Gb electrically connected to the eighth pixel circuit C2-Gb may be disposed in the second pixel row 2R and the fourth pixel column 4C. A ninth light-emitting element E3-R electrically connected to the ninth pixel circuit C3-R may be disposed in the third pixel row 3R and the first pixel column 1C. A tenth light-emitting element E3-B electrically connected to the tenth pixel circuit C3-B may be disposed in the fourth pixel row 4R and the first pixel column 1C. An eleventh light-emitting element E3-Ga electrically connected to the eleventh pixel circuit C3-Ga may be disposed in the third pixel row 3R and the second pixel column 2C. A twelfth light-emitting element E3-Gb electrically connected to the twelfth pixel circuit C3-Gb may be disposed in the fourth pixel row 4R and the second pixel column 2C. A thirteenth light-emitting element E4-B electrically connected to the thirteenth pixel circuit C4-B may be disposed in the third pixel row 3R and the third pixel column 3C. A fourteenth light-emitting element E4-R electrically connected to the fourteenth pixel circuit C4-R may be disposed in the fourth pixel row 4R and the third pixel column 3C. A fifteenth light-emitting element E4-Ga electrically connected to the fifteenth pixel circuit C4-Ga may be disposed in the third pixel row 3R and the fourth pixel column 4C. A sixteenth light-emitting element E4-Gb electrically connected to the sixteenth pixel circuit C4-Gb may be disposed in the fourth pixel row 4R and the fourth pixel column 4C.

In an embodiment, some of the first to sixteenth light-emitting elements may emit light of different colors. For example, each of the first to sixteenth light-emitting elements may emit one of red light, green light, and blue light.

In an embodiment, the first light-emitting element E1-R, the sixth light-emitting element E2-R, the ninth light-emitting element E3-R, and the fourteenth light-emitting element E4-R may be red light-emitting elements that emit red light. The second light-emitting element E1-B, the fifth light-emitting element E2-B, the tenth light-emitting element E3-B, and the thirteenth light-emitting element E4-B may be blue light-emitting elements that emit blue light. The third light-emitting element E1-Ga, the fourth light-emitting element E1-Gb, the seventh light-emitting element E2-Ga, the eighth light-emitting element E2-Gb, the eleventh light-emitting element E3-Ga, the twelfth light-emitting element E3-Gb, the fifteenth light-emitting element E4-Ga, and the sixteenth light-emitting element E4-Gb may be green light-emitting elements that emit green light.

In an embodiment, in each of the pixel rows, an arrangement of the red light-emitting element, the green light-emitting element, the blue light-emitting element, and the green light-emitting element may be repeated.

In an embodiment, in each of odd-numbered pixel columns among the pixel columns, the red light-emitting elements and the blue light-emitting elements may be alternately disposed. In each of even-numbered pixel columns among the pixel columns, only green light-emitting elements may be disposed.

The described arrangement, in which red and blue light-emitting elements alternate in odd-numbered columns while even-numbered columns contain only green light-emitting elements, may also mitigate color crosstalk between adjacent sub-pixels. Because the green sub-pixels are isolated in dedicated columns, interference from adjacent red or blue sub-pixels can be reduced, improving color separation and enhancing image clarity, including in high-contrast or fine-patterned content.

In an embodiment, a first pixel including the first pixel circuit C1-R and the first light-emitting element E1-R, a second pixel including the second pixel circuit C1-B and the second light-emitting element E1-B, a third pixel including the third pixel circuit C1-Ga and the third light-emitting element E1-Ga, and a fourth pixel including the fourth pixel circuit C1-Gb and the fourth light-emitting element E1-Gb may constitute (or form) a first unit pixel UP1.

A fifth pixel including the fifth pixel circuit C2-B and the fifth light-emitting element E2-B, a sixth pixel including the sixth pixel circuit C2-R and the sixth light-emitting element E2-R, a seventh pixel including the seventh pixel circuit C2-Ga and the seventh light-emitting element E2-Ga, and an eighth pixel including the eighth pixel circuit C2-Gb and the eighth light-emitting element E2-Gb may constitute (or form) a second unit pixel UP2.

A ninth pixel including the ninth pixel circuit C3-R and the ninth light-emitting element E3-R, a tenth pixel including the tenth pixel circuit C3-B and the tenth light-emitting element E3-B, an eleventh pixel including the eleventh pixel circuit C3-Ga and the eleventh light-emitting element E3-Ga, and a twelfth pixel including the twelfth pixel circuit C3-Gb and the twelfth light-emitting element E3-Gb may constitute (or form) a third unit pixel UP3.

A thirteenth pixel including the thirteenth pixel circuit C4-B and the thirteenth light-emitting element E4-B, a fourteenth pixel including the fourteenth pixel circuit C4-R and the fourteenth light-emitting element E4-R, a fifteenth pixel including the fifteenth pixel circuit C4-Ga and the fifteenth light-emitting element E4-Ga, and a sixteenth pixel including the sixteenth pixel circuit C4-Gb and the sixteenth light-emitting element E4-Gb may constitute (or form) a fourth unit pixel UP4.

In an embodiment, in each of odd-numbered pixel rows among the pixel rows, an arrangement of a pixel circuit electrically connected to the red light-emitting element (hereinafter, a red pixel circuit), a pixel circuit electrically connected to the blue light-emitting element (hereinafter, a blue pixel circuit), the blue pixel circuit, and the red pixel circuit may be repeated. In each of even-numbered pixel rows among the pixel rows, only pixel circuits electrically connected to the green light-emitting elements (hereinafter, green pixel circuits) may be disposed.

In an embodiment, in each of the pixel columns, the red pixel circuits and the green pixel circuits may be alternately disposed, or the blue pixel circuits and the green pixel circuits may be alternately disposed.

In an embodiment, in a plan view, the pixel circuits, which are electrically connected to the light-emitting elements that emit light of the same color, may have the same shape as each other. For example, in a plan view, the first pixel circuit C1-R, the sixth pixel circuit C2-R, the ninth pixel circuit C3-R, and the fourteenth pixel circuit C4-R, which are the red pixel circuits, may have the same shape as each other. In a plan view, the second pixel circuit C1-B, the fifth pixel circuit C2-B, the tenth pixel circuit C3-B, and the thirteenth pixel circuit C4-B, which are the blue pixel circuits, may have the same shape as each other. In a plan view, the third pixel circuit C1-Ga, the fourth pixel circuit C1-Gb, the seventh pixel circuit C2-Ga, the eighth pixel circuit C2-Gb, the eleventh pixel circuit C3-Ga, the twelfth pixel circuit C3-Gb, the fifteenth pixel circuit C4-Ga, and the sixteenth pixel circuit C4-Gb, which are the green pixel circuits, may have the same shape as each other. Accordingly, it is possible to prevent a luminance deviation that may occur when pixel circuits electrically connected to light-emitting elements that emit light of the same color have different shapes from each other (e.g., shapes that are symmetrical to each other along the second direction DR2) in a plan view. Accordingly, the display quality of the display device DD may be improved.

Furthermore, when pixel circuits of the same color share identical shapes and layouts, the electrical characteristics, such as, e.g., driving transistor channel length, capacitance values, and interconnect resistance, can be matched more closely. This uniformity may facilitate more precise calibration of the data voltages for each color channel, allowing the display device DD to achieve improved color accuracy without requiring extensive per-pixel compensation in the driving algorithm.

In an embodiment, all of the pixel circuits, which are electrically connected to some of the data lines DL1 to DL(2M), may be electrically connected to the light-emitting elements that emit light of the same color. That is, some of the data lines DL1 to DL(2M) may be electrically connected only to the red pixel circuits, the blue pixel circuits, or the green pixel circuits.

For example, as illustrated in FIG. 2, the third pixel circuit C1-Ga, the fourth pixel circuit C1-Gb, the eleventh pixel circuit C3-Ga, and the twelfth pixel circuit C3-Gb, which are the green pixel circuits, may be electrically connected to the second data line DL2, and the red pixel circuits and the blue pixel circuits may be electrically disconnected to (or electrically insulated from) the second data line DL2. Similarly, the seventh pixel circuit C2-Ga, the eighth pixel circuit C2-Gb, the fifteenth pixel circuit C4-Ga, and the sixteenth pixel circuit C4-Gb, which are the green pixel circuits, may be electrically connected to the fourth data line DL4, and the red pixel circuits and the blue pixel circuits may be electrically disconnected to (or electrically insulated from) the fourth data line DL4.

Unlike in FIG. 2, if each of the data lines DL1 to DL(2M) is electrically connected only to the pixel circuits disposed in the corresponding pixel column, all of the data lines DL1 to DL(2M) may be electrically connected to the red pixel circuits and the green pixel circuits, or to the blue pixel circuits and the green pixel circuits. That is, there may be no data line that is electrically connected only to the red pixel circuits, the blue pixel circuits, or the green pixel circuits. For example, in this case, the first data line DL1 may be electrically connected to the first pixel circuit C1-R and the ninth pixel circuit C3-R, which are the red pixel circuits, and may be electrically connected to the third pixel circuit C1-Ga and the eleventh pixel circuit C3-Ga, which are the green pixel circuits. The second data line DL2 may be electrically connected to the second pixel circuit C1-B and the tenth pixel circuit C3-B, which are the blue pixel circuits, and may be electrically connected to the fourth pixel circuit C1-Gb and the twelfth pixel circuit C3-Gb, which are the green pixel circuits. The third data line DL3 may be electrically connected to the fifth pixel circuit C2-B and the thirteenth pixel circuit C4-B, which are the blue pixel circuits, and may be electrically connected to the seventh pixel circuit C2-Ga and the fifteenth pixel circuit C4-Ga, which are the green pixel circuits. The fourth data line DL4 may be electrically connected to the sixth pixel circuit C2-R and the fourteenth pixel circuit C4-R, which are the red pixel circuits, and may be electrically connected to the eighth pixel circuit C2-Gb and the sixteenth pixel circuit C4-Gb, which are the green pixel circuits. That is, because there is no data line that is electrically connected only to the red pixel circuits, the blue pixel circuits, or the green pixel circuits among the first to fourth data lines DL1, DL2, DL3, and DL4, the power consumption of the display device DD may increase.

However, according to embodiments, as illustrated in FIG. 2, only the green pixel circuits may be electrically connected to each of the second data line DL2 and the fourth data line DL4, and the red pixel circuits and the blue pixel circuits may be electrically disconnected to (or electrically insulated from) each of the second data line DL2 and the fourth data line DL4. Accordingly, the power consumption of the display device DD may be reduced.

In this configuration, in an embodiment, dedicating the second data line DL2 and the fourth data line DL4 exclusively to green pixel circuits may also result in displays where green sub-pixels contribute a larger share of perceived luminance. By isolating green pixel driving from red and blue pixel driving, embodiments can improve the green channel's refresh timing and voltage levels independently, potentially reducing motion blur and enhancing luminance stability without increasing total power consumption.

In an embodiment, the pixel circuits, which are electrically connected to the same data line, may be electrically connected to different write gate lines. In addition, the pixel circuits, which are electrically connected to the same data line and disposed in the same pixel row, may be electrically connected to different write gate lines.

For example, as illustrated in FIG. 2, the first pixel circuit C1-R, the second pixel circuit C1-B, the ninth pixel circuit C3-R, and the tenth pixel circuit C3-B, which are electrically connected to the first data line DL1, may be respectively electrically connected to the first to fourth write gate lines GWL1, GWL2, GWL3, and GWL4. The third pixel circuit C1-Ga, the fourth pixel circuit C1-Gb, the eleventh pixel circuit C3-Ga, and the twelfth pixel circuit C3-Gb, which are electrically connected to the second data line DL2, may be respectively electrically connected to the first to fourth write gate lines GWL1, GWL2, GWL3, and GWL4. The fifth pixel circuit C2-B, the sixth pixel circuit C2-R, the thirteenth pixel circuit C4-B, and the fourteenth pixel circuit C4-R, which are electrically connected to the third data line DL3, may be respectively electrically connected to the first to fourth write gate lines GWL1, GWL2, GWL3, and GWL4. The seventh pixel circuit C2-Ga, the eighth pixel circuit C2-Gb, the fifteenth pixel circuit C4-Ga, and the sixteenth pixel circuit C4-Gb, which are electrically connected to the fourth data line DL4, may be respectively electrically connected to the first to fourth write gate lines GWL1, GWL2, GWL3, and GWL4.

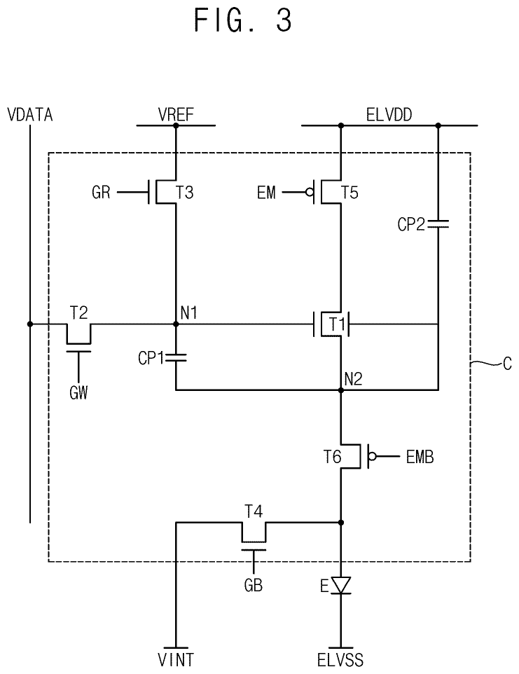

Unlike FIG. 2, if each of the write gate lines GWL1 to GWL(2N) is electrically connected only to the pixel circuits disposed in the corresponding pixel row, two pixel circuits, which are electrically connected to the same data line and disposed in the same pixel row, may be electrically connected to the same write gate line. For example, in this case, both the first pixel circuit C1-R and the second pixel circuit C1-B, which are electrically connected to the first data line DL1 and disposed in the first pixel row 1R, may be electrically connected to the first write gate line GWL1. In this case, a write transistor T2 of the first pixel circuit C1-R and a write transistor T2 of the second pixel circuit C1-B may be simultaneously turned on in response to the write gate signal GW applied from the first write gate line GWL1, thereby transmitting the same data voltage to a first node N1 (see FIG. 3). Therefore, it may be difficult to individually control the operations of the first pixel circuit C1-R and the second pixel circuit C1-B, and it may be difficult to individually control the operations of the first light-emitting element E1-R connected to the first pixel circuit C1-R and the second light-emitting element E1-B connected to the second pixel circuit C1-B.

However, according to embodiments, as illustrated in FIG. 2, the pixel circuits, which are electrically connected to the same data line, may be electrically connected to different write gate lines. Therefore, the operations of the pixel circuits connected to the same data line and the light-emitting elements connected to the pixel circuits may be individually controlled.

By connecting pixel circuits on the same data line to different write gate lines, the driving scheme can selectively update individual pixels without affecting others on the same data path. This selective control may be utilized when displaying fine patterns or text, where maintaining independent modulation of adjacent sub-pixels can prevent color fringing and preserve sharp image edges. Additionally, this configuration may reduce the likelihood of visible artifacts caused by unintentional simultaneous activation of multiple sub-pixels in a shared data line group.

FIG. 3 is an equivalent circuit diagram schematically illustrating a pixel according to an embodiment.

Referring to FIG. 3, each of the pixels may include the pixel circuit C and the light-emitting element E electrically connected to the pixel circuit C. Each of the first to sixteenth pixel circuits described with reference to FIG. 2 may be the same as the pixel circuit C of FIG. 3.

Referring to FIG. 3, in an embodiment, the pixel circuit C may include first to sixth transistors T1, T2, T3, T4, T5, and T6, a first capacitor CP1, and a second capacitor CP2, but the present disclosure is not limited thereto. In an embodiment, the pixel circuit C may include two to five or seven or more transistors and/or one or three or more capacitors.

The first transistor T1 may include a gate electrode connected to a first node N1, a first electrode, and a second electrode connected to a second node N2. In an embodiment, the first transistor T1 may further include a back gate electrode connected to the second node N2. The first transistor T1 may receive the data signal VDATA according to the switching operation of the second transistor T2, and may control the amount of driving current flowing to the light-emitting element E. The first transistor T1 may be referred to as a driving transistor.

In an embodiment, as illustrated in FIG. 3, the first transistor T1 may be implemented as an NMOS transistor. In this case, the first electrode of the first transistor T1 may be a drain electrode, and the second electrode of the first transistor T1 may be a source electrode. However, the present disclosure is not limited thereto.

The second transistor T2 may include a gate electrode to which the write gate signal GW is applied, a first electrode to which the data voltage VDATA is applied, and a second electrode connected to the first node N1. The second transistor T2 may transmit the data voltage VDATA to the first node N1 in response to the write gate signal GW. The second transistor T2 may be referred to as a write transistor.

In an embodiment, as illustrated in FIG. 3, the second transistor T2 may be implemented as an NMOS transistor. In this case, the first electrode of the second transistor T2 may be a drain electrode, and the second electrode of the second transistor T2 may be a source electrode. However, the present disclosure is not limited thereto.

The third transistor T3 may include a gate electrode to which a reference gate signal GR is applied, a first electrode to which a reference voltage VREF is applied, and a second electrode connected to the first node N1. The third transistor T3 may transmit the reference voltage VREF to the first node N1 in response to the reference gate signal GR. The third transistor T3 may be referred to as a reference transistor.

In an embodiment, as illustrated in FIG. 3, the third transistor T3 may be implemented as an NMOS transistor. In this case, the first electrode of the third transistor T3 may be a drain electrode, and the second electrode of the third transistor T3 may be a source electrode. However, the present disclosure is not limited thereto.

The fourth transistor T4 may include a gate electrode to which an initialization gate signal GI is applied, a first electrode to which an initialization voltage VINT is applied, and a second electrode connected to a first electrode of the light-emitting element E. The fourth transistor T4 may transmit the initialization voltage VINT to the first electrode of the light-emitting element E in response to the initialization gate signal GI. The fourth transistor T4 may be referred to as an initialization transistor.

In an embodiment, a first initialization voltage may be applied to the first electrode of the fourth transistor T4 of the green pixel circuit and the first electrode of the fourth transistor T4 of the blue pixel circuit as the initialization voltage VINT, and a second initialization voltage different from the first initialization voltage may be applied to the first electrode of the fourth transistor T4 of the red pixel circuit as the initialization voltage VINT.

In an embodiment, as illustrated in FIG. 3, the fourth transistor T4 may be implemented as an NMOS transistor. In this case, the first electrode of the fourth transistor T4 may be a drain electrode, and the second electrode of the fourth transistor T4 may be a source electrode. However, the present disclosure is not limited thereto.

The fifth transistor T5 may include a gate electrode to which a first emission control signal EM1 is applied, a first electrode to which a first power voltage ELVDD is applied, and a second electrode connected to the first electrode of the first transistor T1. The first power voltage ELVDD may be a high power voltage. The first power voltage ELVDD may be referred to as a driving voltage.

The sixth transistor T6 may include a gate electrode to which a second emission control signal EMB is applied, a first electrode connected to the second node N2, and a second electrode connected to the first electrode of the light-emitting element E.

The fifth transistor T5 may be turned on in response to the first emission control signal EM, and the sixth transistor T6 may be turned on in response to the second emission control signal EMB. The driving current output from the first transistor T1 may flow to the light-emitting element E by the turned-on fifth transistor T5 and sixth transistor T6. The fifth transistor T5 may be referred to as a first emission control transistor, and the sixth transistor T6 may be referred to as a second emission control transistor.

In an embodiment, as illustrated in FIG. 3, each of the fifth transistor T5 and the sixth transistor T6 may be implemented as a PMOS transistor. In this case, the first electrode of the fifth transistor T5 may be a source electrode, and the second electrode of the fifth transistor T5 may be a drain electrode. The first electrode of the sixth transistor T6 may be a source electrode, and the second electrode of the sixth transistor T6 may be a drain electrode. However, the present disclosure is not limited thereto.

The first capacitor CP1 may include a first electrode connected to the first node N1 and a first electrode connected to the second node N2. The first capacitor CP1 may store a voltage corresponding to a threshold voltage of the first transistor T1 and the data voltage VDATA. The first capacitor CP1 may be referred to as a storage capacitor.

The second capacitor CP2 may include a first electrode to which the driving voltage ELVDD is applied, and a second electrode connected to the back gate electrode of the first transistor T1 and the second node N2. The second capacitor may be referred to as a hold capacitor.

The light-emitting element E may include the first electrode and a second electrode to which a second power voltage ELVSS is applied. The first electrode may be a pixel electrode (e.g., an anode electrode), and the second electrode may be a common electrode (e.g., a cathode electrode). The second power voltage ELVSS may be a low power voltage. The second power supply voltage ELVSS may be referred to as a common voltage. The light-emitting element E may emit light based on the driving current provided from the pixel circuit C.

In an embodiment, the second capacitor CP2 may contribute to stable image display by coupling the driving voltage ELVDD to the back gate electrode of the first transistor T1, thereby enabling compensation for threshold voltage variation over time and temperature. By maintaining a more constant potential at the back gate of the first transistor T1 during emission, the second capacitor CP2 may help to preserve consistent drive current to the light-emitting element E, even when variations in the data voltage VDATA or device aging effects might otherwise cause brightness non-uniformity. This arrangement may be utilized in, e.g., a display device operating in hybrid 2D/3D modes, where precise current control is important for maintaining resolution and image quality in the 2D regions.

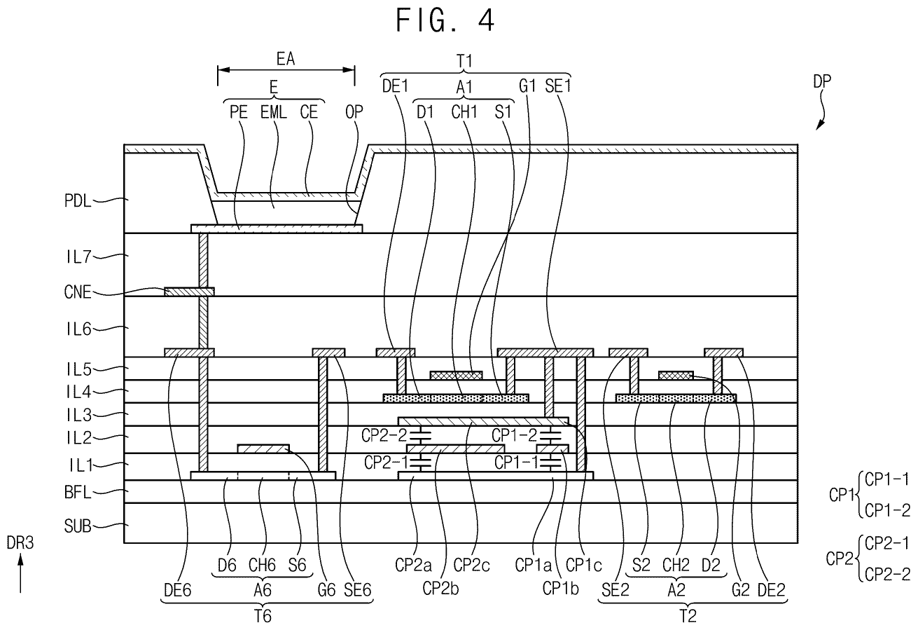

FIG. 4 is a cross-sectional view illustrating a display panel according to an embodiment.

For example, FIG. 4 may illustrates a cross-section corresponding to one of the pixels included in the display panel DP of FIG. 1. In FIG. 4, a third direction DR3 may be perpendicular to the first direction DR1 and the second direction DR2 of FIG. 2, and may represent a thickness direction of the display panel DP. For convenience, FIG. 4 illustrates only the first transistor T1, the second transistor T2, the sixth transistor T6, the first capacitor CP1, and the second capacitor CP2, which are some components of the pixel circuit C of FIG. 3, and the light-emitting element E, and some components are omitted.

Referring to FIGS. 3 and 4, in an embodiment, the display panel DP may include a substrate SUB, a buffer layer BFL, first to seventh insulating layers IL1, IL2, IL3, IL4, IL5, IL6, and IL7, the first transistor T1, the second transistor T2, the sixth transistor T6, the first capacitor CP1, the second capacitor CP2, a pixel connection electrode CNE, the light-emitting element E, and a pixel defining layer PDL.

Each of the first transistor T1, the second transistor T2, and the sixth transistor T6 may include an active layer, a gate electrode, a source electrode, and a drain electrode.

In an embodiment, the first capacitor CP1 may be implemented as a dual capacitor including a first-first capacitor CP1-1 and a first-second capacitor CP1-2, and the second capacitor CP2 may be implemented as a dual capacitor including a second-first capacitor CP2-1 and a second-second capacitor CP2-2. The first-first capacitor CP1-1 may include a first-first capacitor electrode CP1a and a first-second capacitor electrode CP1b, and the first-second capacitor CP1-2 may include the first-second capacitor electrode CP1b and a first-third capacitor electrode CP1c. The second-first capacitor CP2-1 may include a second-first capacitor electrode CP2a and a second-second capacitor electrode CP2b, and the second-second capacitor CP2-2 may include the second-second capacitor electrode CP2b and a second-third capacitor electrode CP2c.

The substrate SUB may form a base of the display panel DP. The substrate SUB may be an insulating substrate formed of a transparent or opaque material. The substrate SUB may be flexible or rigid. The substrate SUB may have a single layer structure or a multi-layer structure in which multiple layers containing different materials are stacked.

The buffer layer BFL may be disposed on the substrate SUB. The buffer layer BFL may prevent or reduce impurities, such as oxygen or moisture, from penetrating into an upper portion of the substrate SUB through the substrate SUB. The buffer layer BFL may include an inorganic material, such as, for example, a silicon compound, a metal oxide, or the like. For example, the buffer layer BFL may include silicon oxide (SiOₓ), silicon nitride (SiNₓ), silicon oxynitride (SiOₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), or other compounds. These may be used alone or in combination with each other. The buffer layer BFL may have a single layer structure or a multi-layer structure including a plurality of insulating layers.

The active layer A6 of the sixth transistor T6, the first-first capacitor electrode CP1a, and the second-first capacitor electrode CP2a may be disposed on the buffer layer BFL.

In an embodiment, the active layer A6 of the sixth transistor T6 may include a silicon semiconductor material. For example, the silicon semiconductor material may include an amorphous silicon, a polycrystalline silicon, or the like. The active layer A6 of the sixth transistor T6 may include a source area S6, a drain area D6, and a channel area CH6 between the source area S6 and the drain area D6. The source area S6 and the drain area D6 may have higher conductivity than the channel area CH6.

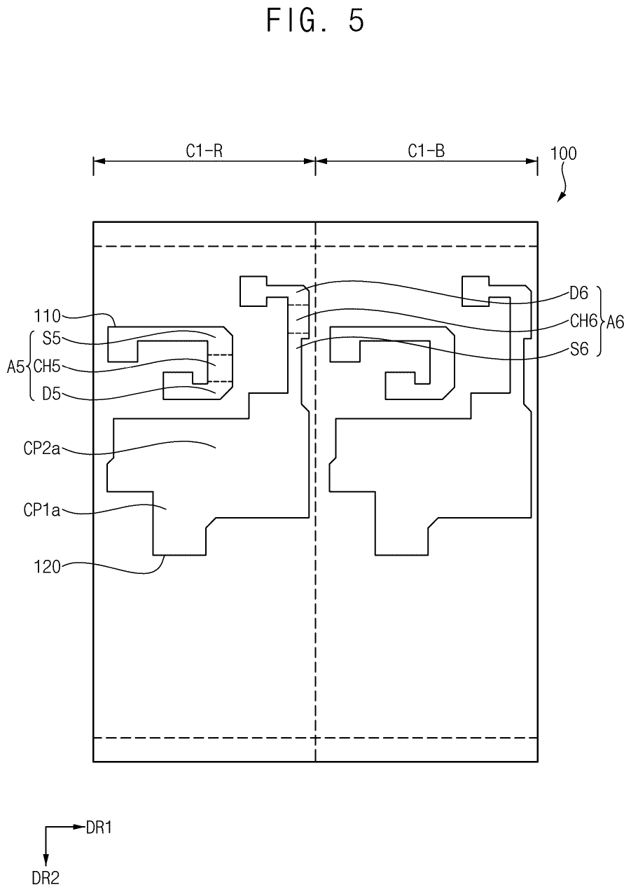

The active layer A6 of the sixth transistor T6, the first-first capacitor electrode CP1a, and the second-first capacitor electrode CP2a may include the same material as each other, and may be substantially simultaneously formed with each other. In an embodiment, the active layer A6 of the sixth transistor T6, the first-first capacitor electrode CP1a, and the second-first capacitor electrode CP2a may be physically integrally connected (or integrally formed) to each other (see FIG. 5). The first-first capacitor electrode CP1a and the second-first capacitor electrode CP2a may have higher conductivity than the channel area CH6.

In an embodiment, the integral formation of the active layer A6 of the sixth transistor T6, the first-first capacitor electrode CP1a, and the second-first capacitor electrode CP2a on the buffer layer BFL may reduce the number of separate patterning and deposition steps, thereby improving manufacturing efficiency and alignment accuracy. This integration may also reduce interface resistance between these elements, reducing parasitic voltage drops and enhancing the charging and discharging characteristics of the capacitors CP1 and CP2. As a result, the pixel circuit C may operate with greater temporal precision during the writing and emission phases, supporting improved resolution retention in the display panel DP.

The first insulating layer IL1 may be disposed on the active layer A6 of the sixth transistor T6, the first-first capacitor electrode CP1a, and the second-first capacitor electrode CP2a. The first insulating layer IL1 may cover the active layer A6 of the sixth transistor T6, the first-first capacitor electrode CP1a, and the second-first capacitor electrode CP2a on the buffer layer BFL. In an embodiment, the first insulating layer IL1 may include an inorganic insulating material, such as a silicon compound, a metal oxide or the like. The first insulating layer IL1 may have a single layer structure or a multi-layer structure including a plurality of insulating layers.

The gate electrode G6 of the sixth transistor T6, the first-second capacitor electrode CP1b, and the second-second capacitor electrode CP2b may be disposed on the first insulating layer IL1.

The gate electrode G6 of the sixth transistor T6 may overlap the channel area CH6 of the active layer A6. The gate electrode G6 of the sixth transistor T6 may include a conductive material, such as, for example, a metal, an alloy, a conductive metal nitride, a conductive metal oxide, a transparent conductive material, or the like. For example, the gate electrode G6 of the sixth transistor T6 may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlNₓ), tungsten nitride (WNₓ), titanium nitride (TiNₓ), chromium nitride (CrNₓ), tantalum nitride (TaNₓ), strontium ruthenium oxide (SrRuOₓ), zinc oxide (ZnOₓ), indium tin oxide (ITO), tin oxide (SnOₓ), indium oxide (InOₓ), gallium oxide (GaOₓ), indium zinc oxide (IZO), or the like. These may be used alone or in combination with each other. The gate electrode G6 of the sixth transistor T6 may have a single layer structure or a multi-layer structure including a plurality of conductive layers.

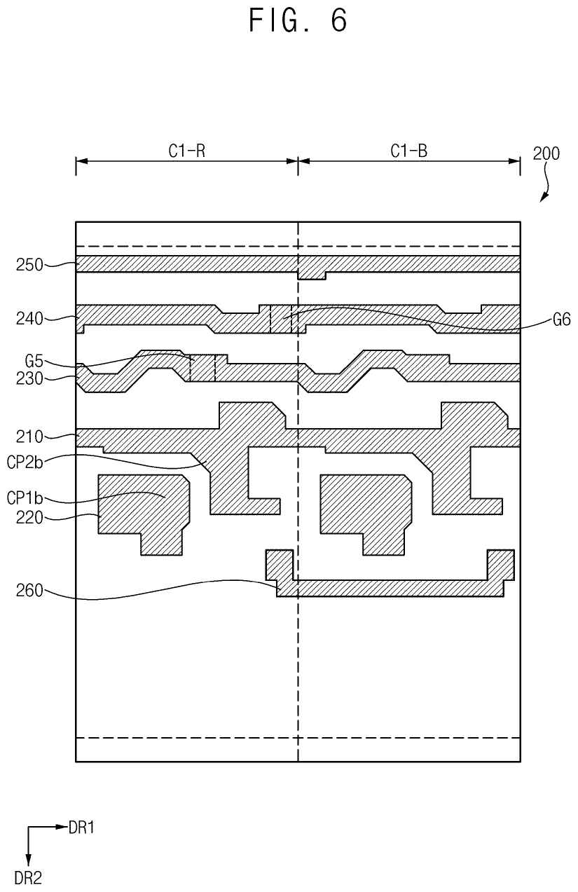

The gate electrode G6 of the sixth transistor T6, the first-second capacitor electrode CP1b, and the second-second capacitor electrode CP2b may include the same material as each other, and may be substantially simultaneously formed with each other. In an embodiment, the gate electrode G6 of the sixth transistor T6, the first-second capacitor electrode CP1b, and the second-second capacitor electrode CP2b may be physically separated from each other (see FIG. 6).

The first-first capacitor electrode CP1a, the first-second capacitor electrode CP1b, and a portion of the first insulating layer IL1 disposed between the first-first capacitor electrode CP1a and the first-second capacitor electrode CP1b may constitute (or form) the first-first capacitor CP1-1.

The second-first capacitor electrode CP2a, the second-second capacitor electrode CP2b, and a portion of the first insulating layer IL1 disposed between the second-first capacitor electrode CP2a and the second-second capacitor electrode CP2b may constitute (or form) the second-first capacitor CP2-1.

The second insulating layer IL2 may be disposed on the gate electrode G6 of the sixth transistor T6, the first-second capacitor electrode CP1b, and the second-second capacitor electrode CP2b. The second insulating layer IL2 may cover the gate electrode G6 of the sixth transistor T6, the first-second capacitor electrode CP1b, and the second-second capacitor electrode CP2b on the first insulating layer IL1. In an embodiment, the second insulating layer IL2 may include an inorganic insulating material, such as a silicon compound, a metal oxide or the like. The second insulating layer IL2 may have a single layer structure or a multi-layer structure including a plurality of insulating layers.

The first-third capacitor electrode CP1c and the second-third capacitor electrode CP2c may be disposed on the second insulating layer IL2.

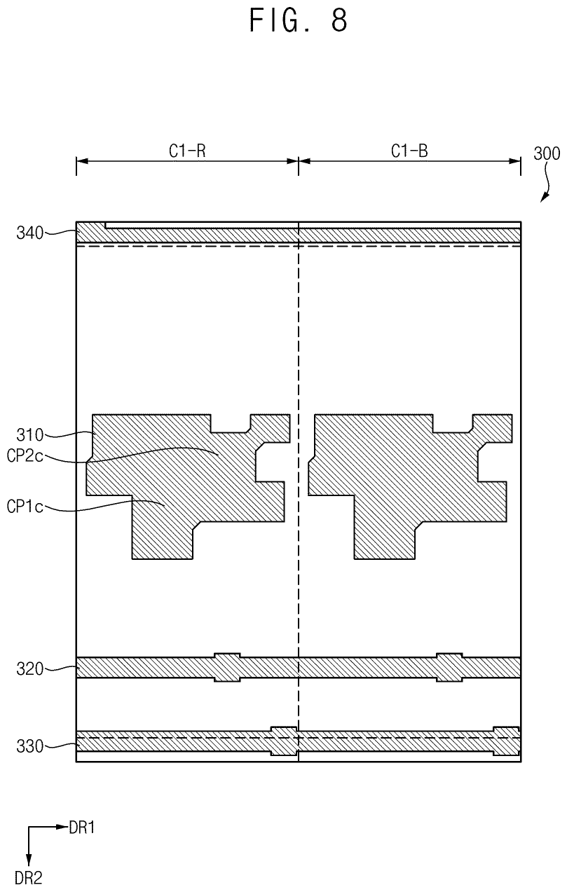

Each of the first-third capacitor electrode CP1c and the second-third capacitor electrode CP2c may include a conductive material, such as, for example, a metal, an alloy, a conductive metal nitride, a conductive metal oxide, a transparent conductive material, or the like. Each of the first-third capacitor electrode CP1c and the second-third capacitor electrode CP2c may have a single layer structure or a multi-layer structure including a plurality of conductive layers. In an embodiment, the first-third capacitor electrode CP1c and the second-third capacitor electrode CP2c may be physically integrally connected (or integrally formed) to each other (see FIG. 8).

The first-second capacitor electrode CP1b, the first-third capacitor electrode CP1c, and a portion of the second insulating layer IL2 disposed between the first-second capacitor electrode CP1b and the first-third capacitor electrode CP1c may constitute (or form) the first-second capacitor CP1-2. The first-third capacitor electrode CP1c may be electrically connected to the first-first capacitor electrode CP1a.

The second-second capacitor electrode CP2b, the second-third capacitor electrode CP2c, and a portion of the second insulating layer IL2 disposed between the second-second capacitor electrode CP2b and the second-third capacitor electrode CP2c may constitute (or form) the second-second capacitor CP2-2. The second-third capacitor electrode CP2c may be electrically connected to the second-first capacitor electrode CP2a.

The third insulating layer IL3 may be disposed on the first-third capacitor electrode CP1c and the second-third capacitor electrode CP2c. The third insulating layer IL3 may cover the first-third capacitor electrode CP1c and the second-third capacitor electrode CP2c on the second insulating layer IL2. In an embodiment, the third insulating layer IL3 may include an inorganic insulating material, such as, for example, a silicon compound, a metal oxide or the like. The third insulating layer IL3 may have a single layer structure or a multi-layer structure including a plurality of insulating layers.

The active layer A1 of the first transistor T1 and the active layer A2 of the second transistor T2 may be disposed on the third insulating layer IL3.

In an embodiment, each of the active layer A1 of the first transistor T1 and the active layer A2 of the second transistor T2 may include an oxide semiconductor material. For example, the oxide semiconductor material may include an oxide of at least one selected from indium (In), gallium (Ga), tin (Sn), zirconium (Zr), vanadium (V), hafnium (Hf), cadmium (Cd), germanium (Ge), chromium (Cr), titanium (Ti), and zinc (Zn).

The active layer A1 of the first transistor T1 may include a source area S1, a drain area D1, and a channel area CH1 between the source area S1 and the drain area D1. The source area S1 and the drain area D1 may have higher conductivity than the channel area CH1. In an embodiment, the channel area CH1 of the active layer A1 of the first transistor T1 may overlap the second-third capacitor electrode CP2c. The second-third capacitor electrode CP2c may be electrically connected to the source area S1 of the active layer A1, and may function as the back gate electrode of the first transistor T1.

In an embodiment, the overlap of the channel area CH1 of the first transistor T1 with the second-third capacitor electrode CP2c may enhance the electrostatic coupling between the capacitor CP2 and the back gate electrode of the first transistor T1. This configuration may enable more accurate modulation of the threshold voltage of the first transistor T1 in accordance with the stored compensation voltage, thereby improving the uniformity of the driving current supplied to the light-emitting element E. By stabilizing the pixel's electrical operating point, this arrangement may prevent resolution degradation in 2D display regions of a hybrid 2D/3D display device.

The active layer A2 of the second transistor T2 may include a source area S2, a drain area D2, and a channel area CH2 between the source area S2 and the drain area D2. The source area S2 and the drain area D2 may have higher conductivity than the channel area CH2.

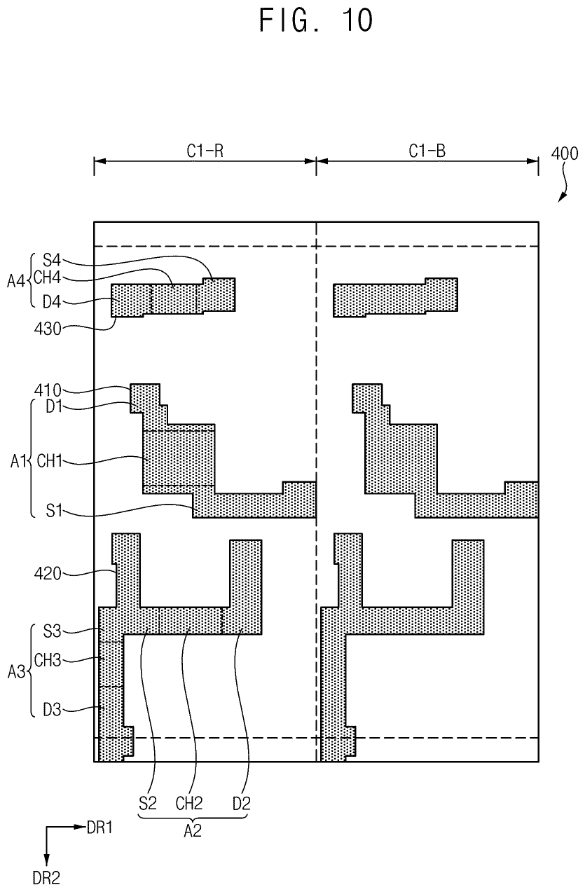

The active layer A1 of the first transistor T1 and the active layer A2 of the second transistor T2 may include the same material as each other, and may be substantially simultaneously formed with each other. In an embodiment, the active layer A1 of the first transistor T1 and the active layer A2 of the second transistor T2 may be physically separated from each other (see FIG. 10).

The fourth insulating layer IL4 may be disposed on the active layer A1 of the first transistor T1 and the active layer A2 of the second transistor T2. The fourth insulating layer IL4 may cover the active layer A1 of the first transistor T1 and the active layer A2 of the second transistor T2 on the third insulating layer IL3. In an embodiment, the fourth insulating layer IL4 may include an inorganic insulating material, such as, for example a silicon compound, a metal oxide or the like. The fourth insulating layer IL4 may have a single layer structure or a multi-layer structure including a plurality of insulating layers.

The gate electrode G1 of the first transistor T1 and the gate electrode G2 of the second transistor T2 may be disposed on the fourth insulating layer IL4.

The gate electrode G1 of the first transistor T1 may overlap the channel area CH1 of the active layer A1. The gate electrode G1 of the first transistor T1 may include a conductive material, such as, for example, a metal, an alloy, a conductive metal nitride, a conductive metal oxide, a transparent conductive material, or the like. The gate electrode G1 of the first transistor T1 may have a single layer structure or a multilayer structure including a plurality of conductive layers.

The gate electrode G2 of the second transistor T2 may overlap the channel area CH2 of the active layer A2. The gate electrode G2 of the second transistor T2 may include a conductive material, such as, for example, a metal, an alloy, a conductive metal nitride, a conductive metal oxide, a transparent conductive material, or the like. The gate electrode G2 of the second transistor T2 may have a single layer structure or a multilayer structure including a plurality of conductive layers.

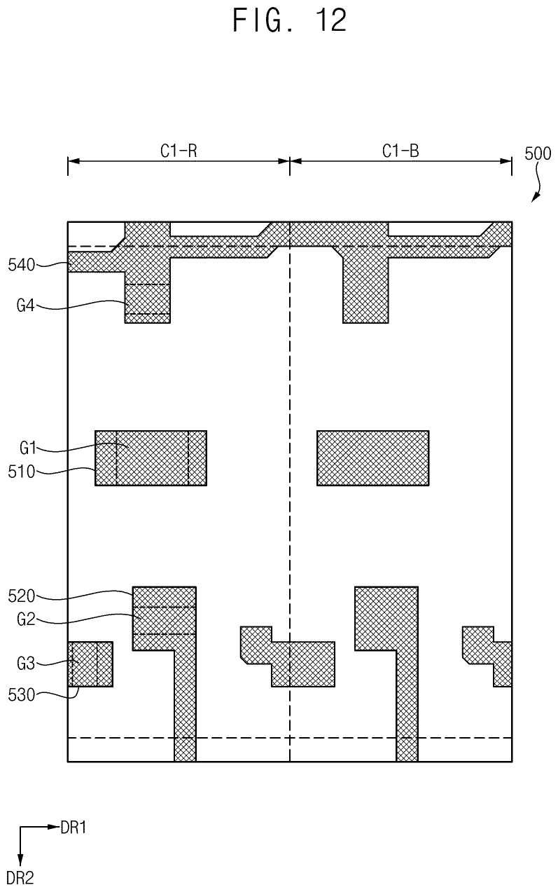

The gate electrode G1 of the first transistor T1 and the gate electrode G2 of the second transistor T2 may include the same material as each other, and may be substantially simultaneously formed with each other. In an embodiment, the gate electrode G1 of the first transistor T1 and the gate electrode G2 of the second transistor T2 may be physically separated from each other (see FIG. 12).

The fifth insulating layer IL5 may be disposed on the gate electrode G1 of the first transistor T1 and the gate electrode G2 of the second transistor T2. The fifth insulating layer IL5 may cover the gate electrode G1 of the first transistor T1 and the gate electrode G2 of the second transistor T2 on the fourth insulating layer IL4. In an embodiment, the fifth insulating layer IL5 may include an inorganic insulating material, such as, for example, a silicon compound, a metal oxide or the like. The fifth insulating layer IL5 may have a single layer structure or a multi-layer structure including a plurality of insulating layers.

The source electrode SE1 and the drain electrode DE1 of the first transistor T1, the source electrode SE2 and the drain electrode DE2 of the second transistor T2, and the source electrode SE6 and the drain electrode DE6 of the sixth transistor T6 may be disposed on the fifth insulating layer IL5.

Each of the source electrodes SE1, SE2, and SE6 and the drain electrodes DE1, DE2, and DE6 may include a conductive material, such as, for example, a metal, an alloy, a conductive metal nitride, a conductive metal oxide, a transparent conductive material, or the like. Each of the source electrodes SE1, SE2, and SE6 and the drain electrodes DE1, DE2, and DE6 may have a single layer structure or a multi-layer structure including a plurality of conductive layers.

The source electrode SE1 and the drain electrode DE1 of the first transistor T1 may be respectively electrically connected to the source area S1 and the drain area D1 of the active layer A1. The source electrode SE2 and the drain electrode DE2 of the second transistor T2 may be respectively electrically connected to the source area S2 and the drain area D2 of the active layer A2. The source electrode SE6 and the drain electrode DE6 of the sixth transistor T6 may be respectively electrically connected to the source area S6 and the drain area D6 of the active layer A6.

The sixth insulating layer IL6 may be disposed on the source electrodes SE1, SE2, and SE6 and the drain electrodes DE1, DE2, and DE6. The sixth insulating layer IL6 may cover the source electrodes SE1, SE2, and SE6 and the drain electrodes DE1, DE2, and DE6 on the fifth insulating layer IL5. In an embodiment, the sixth insulating layer IL6 may include an organic insulating material. For example, the sixth insulating layer IL6 may include a photoresist, a polyacryl-based resin, a polyimide-based resin, a polyamide-based resin, a siloxane-based resin, an acrylic resin, an epoxy-based resin, or the like. These may be used alone or in combination with each other. The sixth insulating layer IL6 may have a single layer structure or a multi-layer structure including a plurality of insulating layers.

The pixel connection electrode CNE may be disposed on the sixth insulating layer IL6. The pixel connection electrode CNE may include a conductive material, such as, for example, a metal, an alloy, a conductive metal nitride, a conductive metal oxide, a transparent conductive material, or the like. The pixel connection electrode CNE may have a single layer structure or a multi-layer structure including a plurality of conductive layers. The pixel connection electrode CNE may be electrically connected to the drain electrode DE6 of the sixth transistor T6.

The seventh insulating layer IL7 may be disposed on the pixel connection electrode CNE. The seventh insulating layer IL7 may cover the pixel connection electrode CNE on the sixth insulating layer IL6. In an embodiment, the seventh insulating layer IL7 may include an organic insulating material. The seventh insulating layer IL7 may have a single layer structure or a multi-layer structure including a plurality of insulating layers.

The light-emitting element E may be disposed on the seventh insulating layer IL7. The light-emitting element E may include a pixel electrode PE, an emission layer EML, and a common electrode CE.

The pixel electrode PE may be disposed on the seventh insulating layer IL7. The pixel electrode PE may include a conductive material, such as, for example, a metal, an alloy, a conductive metal nitride, a conductive metal oxide, a transparent conductive material, or the like. The pixel electrode PE may have a single layer structure or a multi-layer structure including a plurality of conductive layers. The pixel electrode PE may be electrically connected to the pixel connection electrode CNE. Accordingly, the pixel electrode PE may be electrically connected to the sixth transistor T6. For example, the pixel electrode PE may function as the anode electrode of the light-emitting element E.

The pixel defining layer PDL may be disposed on the pixel electrode PE. The pixel defining layer PDL may cover a peripheral portion of the pixel electrode PE, and may define a pixel opening OP that exposes a central portion of the pixel electrode PE. An emission area EA, which is an area where light is emitted from the light-emitting element E, may be defined by the pixel opening OP. The pixel defining layer PDL may include an organic insulating material. In an embodiment, the pixel defining layer PDL may further include an inorganic material or an organic material including a light blocking material having a black color.

The emission layer EML may be disposed on the pixel electrode PE and the pixel defining layer PDL. For example, the emission layer EML may be disposed in the pixel opening OP of the pixel defining layer PDL. The emission layer EML may include an emission material, such as, for example, an organic emission material, an inorganic emission material, or the like.

The common electrode CE may be disposed on the emission layer EML. The common electrode CE may also be disposed on the pixel defining layer PDL. For example, the common electrode CE may be disposed on the entire display area of the display panel DP. The common electrode CE may include a conductive material, such as, for example, a metal, an alloy, a conductive metal nitride, a conductive metal oxide, a transparent conductive material, or the like. The common electrode CE may have a single layer structure or a multi-layer structure including a plurality of conductive layers. The common voltage ELVSS may be applied to the common electrode CE. For example, the common electrode CE may function as the cathode electrode of the light-emitting element E.

In an embodiment, the light-emitting element E may further include functional layers disposed between the pixel electrode PE and the emission layer EML and/or between the emission layer EML and the common electrode CE. The functional layers may include, for example, a hole injection layer, a hole transport layer, an electron transport layer, and/or an electron injection layer.

In an embodiment, the display panel DP may further include various layers, such as, for example, a thin film encapsulation layer, a touch sensing layer, an anti-reflection layer, or the like disposed on the common electrode CE.

FIGS. 5 to 19 are layout views illustrating a pixel according to an embodiment.

FIGS. 5 to 19 illustrate the first pixel circuit C1-R and the second pixel circuit C1-B of FIG. 2. FIGS. 5 to 19 illustrate some of layers included in the display panel DP. Hereinafter, for convenience of description, the structure of the first pixel including the first pixel circuit C1-R and the first light-emitting element E1-R connected to the first pixel circuit C1-R will be described in more detail, and the description described later may be substantially equally or similarly applied to other pixels.

Referring to FIGS. 2 to 19, in an embodiment, the display panel DP may include a first semiconductor layer 100, a first conductive layer 200, a second conductive layer 300, a second semiconductor layer 400, a third conductive layer 500, a fourth conductive layer 600, a fifth conductive layer 700, and a sixth conductive layer 800 disposed on the buffer layer BFL.

FIG. 5 illustrates the first semiconductor layer 100.

As illustrated in FIGS. 2 to 5, the first semiconductor layer 100 may be disposed on the buffer layer BFL. In an embodiment, the first semiconductor layer 100 may include a silicon semiconductor material.

In an embodiment, the first semiconductor layer 100 may include a first semiconductor pattern 110 and a second semiconductor pattern 120. The first semiconductor pattern 110 and the second semiconductor pattern 120 may be spaced apart from each other in a plan view.

The first semiconductor pattern 110 may include the active layer A5 of the fifth transistor T5. The active layer A5 of the fifth transistor T5 may include a source area S5, a drain area D5, and a channel area CH5 between the source area S5 and the drain area D5. The source area S5 and the drain area D5 may have higher conductivity than the channel area CH5. In an embodiment, the source area S5, the channel area CH5, and the drain area D5 may be sequentially disposed in the second direction DR2. The source area S5 may be the first electrode of the fifth transistor T5, the drain area D5 may be the second electrode of the fifth transistor T5, and the channel area CH5 may be a channel of the fifth transistor T5.

The second semiconductor pattern 120 may include the active layer A6 of the sixth transistor T6, the first-first capacitor electrode CP1a, and the second-first capacitor electrode CP2a. The active layer A6 of the sixth transistor T6 may include the source area S6, the drain area D6, and the channel area CH6 between the source area S6 and the drain area D6. In an embodiment, the drain area D6, the channel area CH6, and the source area S6 may be sequentially disposed in the second direction DR2. The source area S6 may be the first electrode of the sixth transistor T6, the drain area D6 may be the second electrode of the sixth transistor T6, and the channel area CH6 may be a channel of the sixth transistor T6.

The first-first capacitor electrode CP1a may be a portion of the second semiconductor pattern 120 that overlaps a first driving voltage line 210 of the second conductive layer 200 described later in a plan view. The first-first capacitor electrode CP1a may be the second electrode of the first capacitor CP1.

The second-first capacitor electrode CP2a may be a portion of the second semiconductor pattern 120 that overlaps a second conductive pattern 220 of the second conductive layer 200 described later in a plan view. The second-first capacitor electrode CP2a may be the second electrode of the second capacitor CP2.

The source area S6 of the sixth transistor T6, the second-first capacitor electrode CP2a, and the first-first capacitor electrode CP1a may be physically integrally connected (or integrally formed) to each other. Accordingly, the first electrode of the sixth transistor T6, the second electrode of the first capacitor CP1, and the second electrode of the second capacitor CP2 may be electrically connected to each other.

The first insulating layer IL1 may be disposed on the first semiconductor layer 100.

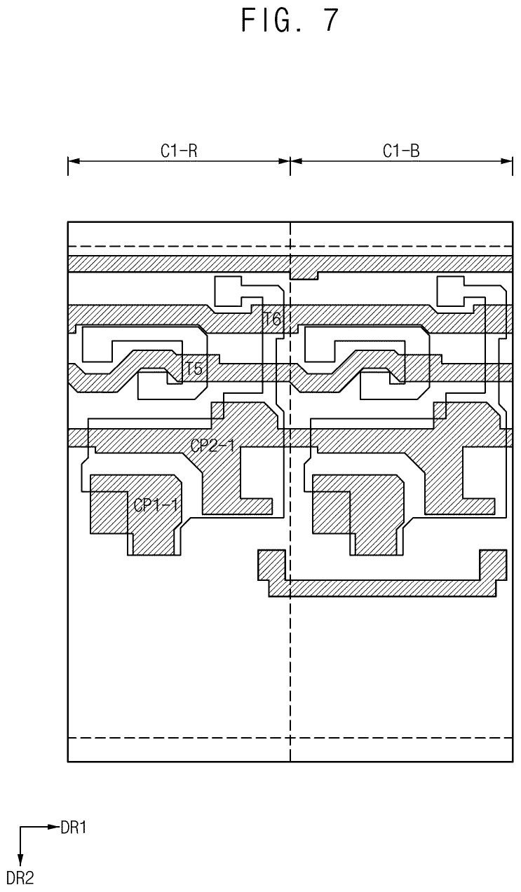

FIG. 6 illustrates the first conductive layer 200, and FIG. 7 illustrates the view of FIG. 5 with the first conductive layer 200 further disposed.

As illustrated in FIGS. 2 to 7, the first conductive layer 200 may be disposed on the first insulating layer IL1. The first conductive layer 200 may include a conductive material.

In an embodiment, the first conductive layer 200 may include the first driving voltage line 210, the first conductive pattern 220, a first emission control line 230, a second emission control line 240, a first initialization voltage line 250, and a data connection line 260. The first driving voltage line 210, the first conductive pattern 220, the first emission control line 230, the second emission control line 240, the first initialization voltage line 250, and the data connection line 260 may be spaced apart from each other in a plan view.

The driving voltage ELVDD may be applied to the first driving voltage line 210. In an embodiment, the first driving voltage line 210 may extend generally in the first direction DR1. The first driving voltage line 210 may include a protruding portion that protrudes in the second direction DR2.

The first driving voltage line 210 may include the second-second capacitor electrode CP2b. The first driving voltage line 210 may partially overlap the second semiconductor pattern 120 in a plan view. The second-second capacitor electrode CP2b may be a portion of the first driving voltage line 210 that overlaps the second semiconductor pattern 120 in a plan view. The second-first capacitor electrode CP2a of the second semiconductor pattern 120 and the second-second capacitor electrode CP2b of the first driving voltage line 210 may constitute (or form) the second-first capacitor CP2-1. The second-second capacitor electrode CP2b may be the first electrode of the second capacitor CP2.

The first conductive pattern 220 may include the first-second capacitor electrode CP1b. In an embodiment, the first conductive pattern 220 may be spaced apart from the first driving voltage line 210 in the second direction DR2. The first conductive pattern 220 may partially overlap the second semiconductor pattern 120 in a plan view. The first-second capacitor electrode CP1b may be a portion of the first conductive pattern 220 that overlaps the second semiconductor pattern 120 in a plan view. The first-first capacitor electrode CP1a of the second semiconductor pattern 120 and the first-second capacitor electrode CP1b of the first conductive pattern 220 may constitute (or form) the first-first capacitor CP1-1. The first-second capacitor electrode CP1b may be the first electrode of the first capacitor CP1.

The first emission control signal EM may be applied to the first emission control line 230. In an embodiment, the first emission control line 230 may extend generally in the first direction DR1. The first emission control line 230 may be spaced apart from the first driving voltage line 210 in a direction opposite to the second direction DR2.

The first emission control line 230 may partially overlap the first semiconductor pattern 110 in a plan view. The first emission control line 230 may overlap the channel area CH5 of the active layer A5 of the fifth transistor T5 in a plan view. A portion of the first emission control line 230, which overlaps the channel area CH5 in a plan view, may be the gate electrode G5 of the fifth transistor T5.

The second emission control signal EMB may be applied to the second emission control line 240. In an embodiment, the second emission control line 240 may extend generally in the first direction DR1. The second emission control line 240 may be spaced apart from the first emission control line 230 in the direction opposite to the second direction DR2.

The second emission control line 240 may partially overlap the second semiconductor pattern 120 in a plan view. The second emission control line 240 may overlap the channel area CH6 of the active layer A6 of the sixth transistor T6 in a plan view. A portion of the second emission control line 240, which overlaps the channel area CH6 in a plan view, may be the gate electrode G6 of the sixth transistor T6.

The first initialization voltage may be applied to the first initialization voltage line 250. In an embodiment, the first initialization voltage line 250 may extend generally in the first direction DR1. The first initialization voltage line 250 may be spaced apart from the second emission control line 240 in the direction opposite to the second direction DR2.

In an embodiment, the data connection line 260 may extend generally in the first direction DR1. One data connection line 260 may be disposed to correspond to both the first pixel circuit C1-R and the second pixel circuit C1-B. The data connection line 260 may include a first portion overlapping the first pixel circuit C1-R and a second portion overlapping the second pixel circuit C1-B. The data connection line 260 may transmit the data voltage from the first data line DL1 overlapping the first pixel circuit C1-R to the second pixel circuit C1-B. This will be described later with reference to FIGS. 20 to 22.

The second insulating layer IL2 may be disposed on the first conductive layer 200.

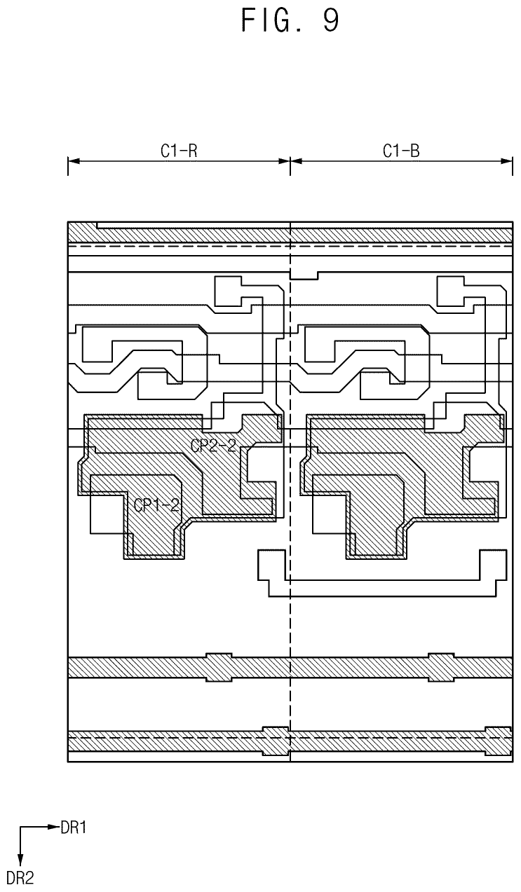

FIG. 8 illustrates the second conductive layer 300, and FIG. 9 illustrates the view of FIG. 7 with the second conductive layer 300 further disposed.

As illustrated in FIGS. 2 to 4, 8, and 9, the second conductive layer 300 may be disposed on the second insulating layer IL2. The second conductive layer 300 may include a conductive material.

In an embodiment, the second conductive layer 300 may include a second conductive pattern 310, a reference gate line 320, a reference voltage line 330, and a second initialization voltage line 340. The second conductive pattern 310, the reference gate line 320, the reference voltage line 330, and the second initialization voltage line 340 may be spaced apart from each other in a plan view.

In an embodiment, the second conductive pattern 310 may partially overlap each of the first driving voltage line 210 and the first conductive pattern 220 in a plan view. The second conductive pattern 310 may include the first-third capacitor electrode CP1c and the second-third capacitor electrode CP2c.

The first-third capacitor electrode CP1c may be a portion of the second conductive pattern 310 that overlaps the first conductive pattern 220 in a plan view. The first-second capacitor electrode CP1b of the first conductive pattern 220 and the first-third capacitor electrode CP1c of the second conductive pattern 310 may constitute (or form) the first-second capacitor CP1-2. The first-third capacitor electrode CP1c may be the second electrode of the first capacitor CP1.

The second-third capacitor electrode CP2c may be a portion of the second conductive pattern 310 that overlaps the first driving voltage line 210 in a plan view. The second-second capacitor electrode CP2 b of the first driving voltage line 210 and the second-third capacitor electrode CP2c of the second conductive pattern 310 may constitute (or form) the second-second capacitor CP2-2. The second-third capacitor electrode CP2c may be the second electrode of the second capacitor CP2.

The first-third capacitor electrode CP1c and the second-third capacitor electrode CP2c may be physically integrally connected (or integrally formed) to each other. Accordingly, the second electrode of the first capacitor CP1 and the second electrode of the second capacitor CP2 may be electrically connected to each other.

In an embodiment, the second conductive pattern 310 may partially overlap a third semiconductor pattern 410 described later in a plan view. A portion of the second conductive pattern 310, which overlaps the third semiconductor pattern 410 in a plan view, may be the back gate electrode of the first transistor T1.

The reference gate signal GR may be applied to the reference gate line 320. In an embodiment, the reference gate line 320 may extend generally in the first direction DR1. The reference gate line 320 may be spaced apart from the second conductive pattern 310 in the second direction DR2.

The reference voltage VREF may be applied to the reference voltage line 330. In an embodiment, the reference voltage line 330 may extend generally in the first direction DR1. The reference voltage line 330 may be spaced apart from the reference gate line 320 in the second direction DR2.

The second initialization voltage may be applied to the second initialization voltage line 340. In an embodiment, the second initialization voltage line 340 may extend generally in the first direction DR1. The second initialization voltage line 340 may be spaced apart from the second conductive pattern 310 in the direction opposite to the second direction DR2.

The third insulating layer IL3 may be disposed on the second conductive layer 300.

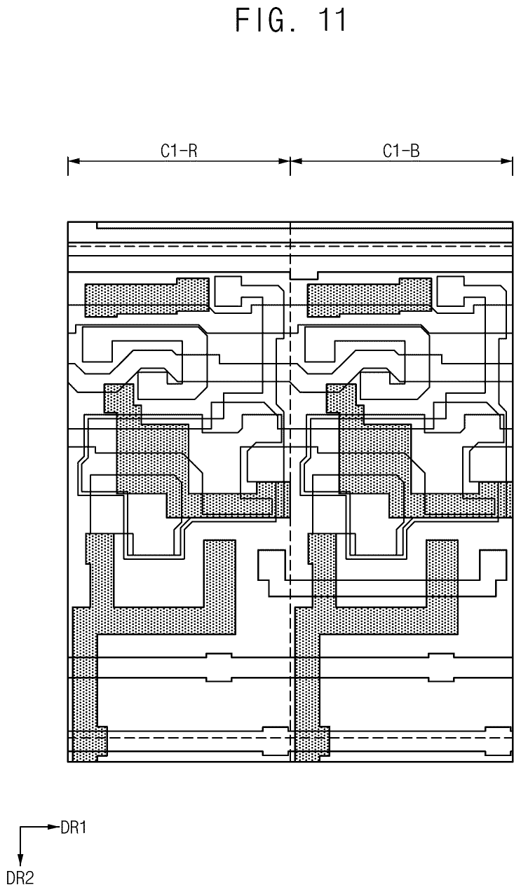

FIG. 10 illustrates the second semiconductor layer 400, and FIG. 11 illustrates the view of FIG. 0 with the second semiconductor layer 400 further disposed.

As illustrated in FIGS. 2 to 4, 10, and 11, the second semiconductor layer 400 may be disposed on the third insulating layer IL3. In an embodiment, the second semiconductor layer 400 may include an oxide semiconductor material.

In an embodiment, the second semiconductor layer 400 may include a third semiconductor pattern 410, a fourth semiconductor pattern 420, and a fifth semiconductor pattern 430. The third semiconductor pattern 410, the fourth semiconductor pattern 420, and the fifth semiconductor pattern 430 may be spaced apart from each other in a plan view.

The third semiconductor pattern 410 may include the active layer A1 of the first transistor T1. The active layer A1 of the first transistor T1 may include the source area S1, the drain area D1, and the channel area CH1 between the source area S1 and the drain area D1. The source area S1 and the drain area D1 may have higher conductivity than the channel area CH1. In an embodiment, the drain area D1, the channel area CH1, and the source area S1 may be sequentially disposed in the second direction DR2. The drain area D1 may be the first electrode of the first transistor T1, the source area S1 may be the second electrode of the first transistor T1, and the channel area CH1 may be a channel of the first transistor T1.

In an embodiment, the fourth semiconductor pattern 420 may be spaced apart from the third semiconductor pattern 410 in the second direction DR2. The fourth semiconductor pattern 420 may include the active layer A2 of the second transistor T2 and the active layer A3 of the third transistor T3.

The active layer A2 of the second transistor T2 may include the source area S2, the drain area D2, and the channel area CH2 between the source area S2 and the drain area D2. The source area S2 and the drain area D2 may have higher conductivity than the channel area CH2. In an embodiment, the source area S2, the channel area CH2, and the drain area D2 may be sequentially disposed in the first direction DR1. The drain area D2 may be the first electrode of the second transistor T2, the source area S2 may be the second electrode of the second transistor T2, and the channel area CH2 may be a channel of the second transistor T2.

The active layer A3 of the third transistor T3 may include a source area S3, a drain area D3, and a channel area CH3 between the source area S3 and the drain area D3. The source area S3 and the drain area D3 may have higher conductivity than the channel area CH3. In an embodiment, the source area S3, the channel area CH3, and the drain area D3 may be sequentially disposed in the second direction DR2. The drain area D3 may be the first electrode of the third transistor T3, the source area S3 may be the second electrode of the third transistor T3, and the channel area CH3 may be a channel of the third transistor T3.

The source area S2 of the second transistor T2 and the source area S3 of the third transistor T3 may be physically integrally connected (or integrally formed) to each other. Accordingly, the second electrode of the second transistor T2 and the second electrode of the third transistor T3 may be electrically connected to each other.

In an embodiment, the fifth semiconductor pattern 430 may be spaced apart from the third semiconductor pattern 410 in the direction opposite to the second direction DR2. The fifth semiconductor pattern 430 may include the active layer A4 of the fourth transistor T4.

The active layer A4 of the fourth transistor T4 may include a source area S4, a drain area D4, and a channel area CH4 between the source area S4 and the drain area D4. The source area S4 and the drain area D4 may have higher conductivity than the channel area CH4. In an embodiment, the drain area D4, the channel area CH4, and the source area S4 may be sequentially disposed in the first direction DR1. The drain area D4 may be the first electrode of the fourth transistor T4, the source area S4 may be the second electrode of the fourth transistor T4, and the channel area CH4 may be a channel of the fourth transistor T4.

The fourth insulating layer IL4 may be disposed on the second semiconductor layer 400.

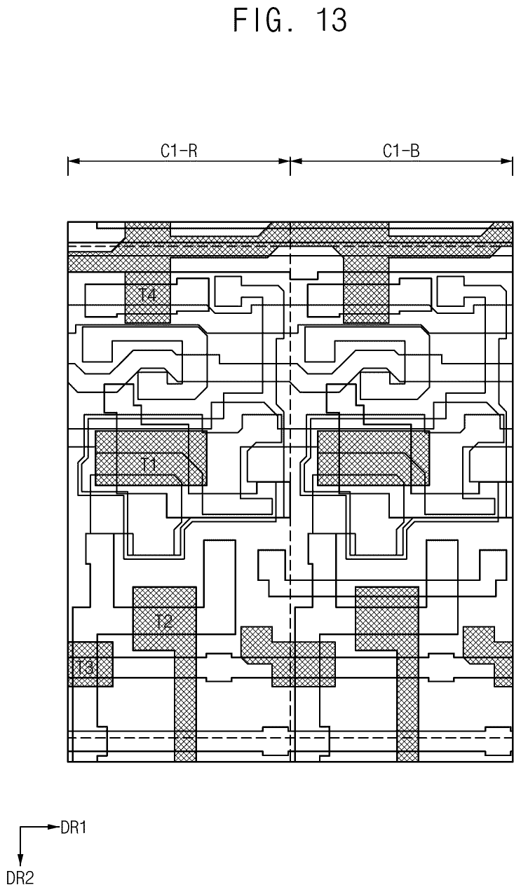

FIG. 12 illustrates the third conductive layer 500, and FIG. 13 illustrates the view of FIG. 11 with the third conductive layer 500 further disposed.

As illustrated in FIGS. 2 to 4, 12, and 13, the third conductive layer 500 may be disposed on the fourth insulating layer IL4. The third conductive layer 500 may include a conductive material.

In an embodiment, the third conductive layer 500 may include a third conductive pattern 510, a gate connection line 520, a fourth conductive pattern 530, and an initialization gate line 540. The third conductive pattern 510, the gate connection line 520, the fourth conductive pattern 530, and the initialization gate line 540 may be spaced apart from each other in a plan view.

The third conductive pattern 510 may partially overlap the third semiconductor pattern 410 in a plan view. The third conductive pattern 510 may overlap the channel area CH1 of the active layer A1 of the first transistor T1 in a plan view. A portion of the third conductive pattern 510, which overlaps the channel area CH1 in a plan view, may be the gate electrode G1 of the first transistor T1.

The gate connection line 520 may partially overlap the fourth semiconductor pattern 420 in a plan view. The gate connection line 520 may overlap the channel area CH2 of the active layer A2 of the second transistor T2 in a plan view. A portion of the gate connection line 520, which overlaps the channel area CH2 in a plan view, may be the gate electrode G2 of the second transistor T2.

In an embodiment, the gate connection line 520 may extend generally in the second direction DR2. One gate connection line 520 may be disposed to correspond to both the first pixel circuit C1-R and the third pixel circuit C1-Ga (see FIG. 20). The gate connection line 520 may transmit the write gate signal from the first write gate line GWL1 overlapping the first pixel circuit C1-R to the third pixel circuit C1-Ga. This will be described later with reference to FIGS. 20 to 22.

The fourth conductive pattern 530 may partially overlap the fourth semiconductor pattern 420 in a plan view. The fourth conductive pattern 530 may overlap the channel area CH3 of the active layer A3 of the third transistor T3 in a plan view. A portion of the fourth conductive pattern 530, which overlaps the channel area CH3 in a plan view, may be the gate electrode G3 of the third transistor T3.

The initialization gate signal GI may be applied to the initialization gate line 540. In an embodiment, the initialization gate line 540 may extend generally in the first direction DR1. The initialization gate line 540 may include a protruding portion that protrudes in the second direction DR2.

The initialization gate line 540 may partially overlap the fifth semiconductor pattern 430 in a plan view. The protruding portion of the initialization gate line 540 may overlap the channel area CH4 of the active layer A4 of the fourth transistor T4 in a plan view. A portion of the protruding portion of the initialization gate line 540, which overlaps the channel area CH4 in a plan view, may be the gate electrode G4 of the fourth transistor T4.

The fifth insulating layer IL5 may be disposed on the third conductive layer 500.

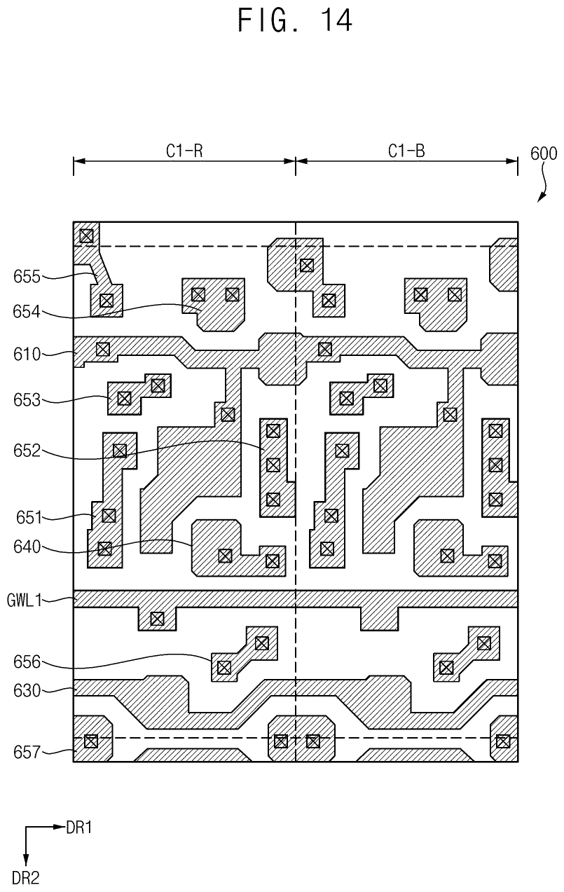

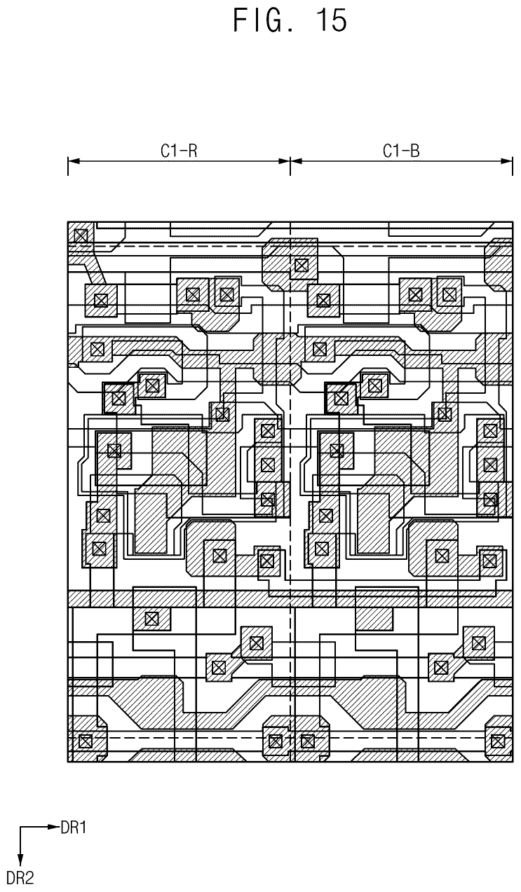

FIG. 14 illustrates the fourth conductive layer 600, and FIG. 15 illustrates the view of FIG. 13 with the fourth conductive layer 600 further disposed.

As illustrated in FIGS. 2 to 4, 14, and 15, the fourth conductive layer 600 may be disposed on the fifth insulating layer IL5. The fourth conductive layer 600 may include a conductive material.

In an embodiment, the fourth conductive layer 600 may include a second driving voltage line 610, the first write gate line GWL 1, a horizontal transmission line 630, a data connection pattern 640, a first connection electrode 651, a second connection electrode 652, a third connection electrode 653, a fourth connection electrode 654, a fifth connection electrode 655, a sixth connection electrode 656, and a seventh connection electrode 657. The second driving voltage line 610, the first write gate line GWL 1, the horizontal transmission line 630, the data connection pattern 640, the first connection electrode 651, the second connection electrode 652, the third connection electrode 653, the fourth connection electrode 654, the fifth connection electrode 655, the sixth connection electrode 656, and the seventh connection electrode 657 may be spaced apart from each other in a plan view.

In an embodiment, the second driving voltage line 610 may extend generally in the first direction DR1. The second driving voltage line 610 may include a protruding portion that protrudes in the second direction DR2.

The second driving voltage line 610 may partially overlap the first driving voltage line 210 of FIG. 6 in a plan view. A first portion of the second driving voltage line 610 may overlap the first driving voltage line 210 in a plan view. The first portion of the second driving voltage line 610 may contact the first driving voltage line 210 through a contact hole. Accordingly, the driving voltage ELVDD may be applied to the second driving voltage line 610 through the first driving voltage line 210.

The second driving voltage line 610 may partially overlap the first semiconductor pattern 110 of FIG. 5 in a plan view. A second portion of the second driving voltage line 610 may overlap the first semiconductor pattern 110 in a plan view. The second portion of the second driving voltage line 610 may contact the source area S5 of the fifth transistor T5 of the first semiconductor pattern 110 through a contact hole. Accordingly, the driving voltage ELVDD may be applied to the first electrode of the fifth transistor T5 through the first driving voltage line 210 and the second driving voltage line 610.

The write gate signal GW may be applied to the first write gate line GWL1. In an embodiment, the first write gate line GWL1 may extend generally in the first direction DR1. The first write gate line GWL1 may be spaced apart from the second driving voltage line 610 in the second direction DR2.

The first write gate line GWL1 may partially overlap the gate connection line 520 of FIG. 12 in a plan view. A first portion of the first write gate line GWL1 may overlap the gate connection line 520 in a plan view. The first portion of the first write gate line GWL 1 may contact the gate connection line 520 through a contact hole. Accordingly, the write gate signal GW may be applied to the gate electrode G2 of the second transistor T2 of the first pixel circuit C1-R and the gate electrode G2 of the second transistor T2 of the third pixel circuit C1-Ga through the first write gate line GWL1.

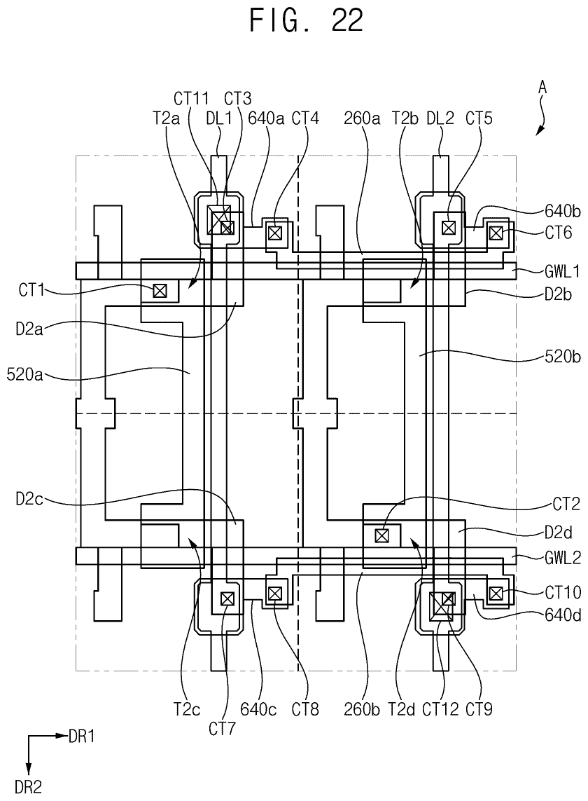

As illustrated in FIGS. 14 and 15, the first write gate line GWL1 may partially overlap an adjacent gate connection line (e.g., a second gate connection line 520b of FIG. 22), which is disposed to correspond to the second pixel circuit C1-B of FIG. 12, in a plan view. A second portion of the first write gate line GWL1 may overlap the adjacent gate connection line in a plan view. A contact hole may not be formed between the second portion of the first write gate line GWL1 and the adjacent gate connection line. That is, the second portion of the first write gate line GWL1 may be electrically disconnected to (or electrically insulated from) the adjacent gate connection line. This will be described later with reference to FIGS. 20 to 22.

In an embodiment, the horizontal transmission line 630 may extend generally in the first direction DR1. The horizontal transmission line 630 may be spaced apart from the first write gate line GWL1 in the second direction DR2.

In an embodiment, the data connection pattern 640 may be spaced apart from the first write gate line GWL1 in the direction opposite to the second direction DR2. The data connection pattern 640 may partially overlap each of the data connection line 260 of FIG. 6 and the fourth semiconductor pattern 420 of FIG. 10 in a plan view. A first portion of the data connection pattern 640 may overlap the first portion of the data connection line 260 in a plan view, and a second portion of the data connection pattern 640 may overlap the fourth semiconductor pattern 420 in a plan view. The first portion of the data connection pattern 640 may contact the first portion of the data connection line 260 through a contact hole, and the second portion of the data connection pattern 640 may contact the drain area D2 of the second transistor T2 of the fourth semiconductor pattern 420 through a contact hole. Accordingly, the data connection line 260 and the first electrode of the second transistor T2 of the first pixel circuit C1-R may be electrically connected through the data connection pattern 640.

As illustrated in FIGS. 14 and 15, a first adjacent data connection pattern (e.g., a second data connection pattern 640b of FIG. 22), which is disposed to correspond to the second pixel circuit C1-B, may electrically connect the second portion of the data connection line 260 and the first electrode (e.g., a drain area D2b of FIG. 22) of the second transistor T2 of the second pixel circuit C1-B. This will be described later with reference to FIGS. 20 to 22.

The first connection electrode 651 may be electrically connected to the first conductive pattern 220, the fourth semiconductor pattern 420, and the third conductive pattern 510 through contact holes. Accordingly, the gate electrode G1 of the first transistor T1, the second electrode of the second transistor T2, and the first electrode of the first capacitor CP1 may be electrically connected to each other through the first connection electrode 651.

The second connection electrode 652 may be electrically connected to the second semiconductor pattern 120, the second conductive pattern 310, and the third semiconductor pattern 410 through contact holes. Accordingly, the second electrode of the first transistor T1, the first electrode of the sixth transistor T6, and the second electrode of the second capacitor CP2 may be electrically connected to each other through the second connection electrode 652.

The third connection electrode 653 may be electrically connected to the first semiconductor pattern 110 and the third semiconductor pattern 410 through contact holes. Accordingly, the first electrode of the first transistor T1 and the second electrode of the fifth transistor T5 may be electrically connected to each other through the third connection electrode 653.

The fourth connection electrode 654 may be electrically connected to the second semiconductor pattern 120 and the fifth semiconductor pattern 430 through contact holes. Accordingly, the second electrode of the fourth transistor T4 and the second electrode of the sixth transistor T6 may be electrically connected to each other through the fourth connection electrode 654.

The fifth connection electrode 655 may be electrically connected to the second initialization voltage line 340 and the fifth semiconductor pattern 430 through contact holes. Accordingly, the second initialization voltage may be applied to the first electrode of the fourth transistor T4 through the fifth connection electrode 655.

The sixth connection electrode 656 may be electrically connected to the reference gate line 320 and an adjacent fourth conductive pattern, which is disposed to correspond to the second pixel circuit C1-B, through contact holes. Accordingly, the reference gate signal GR may be applied to the gate electrode of the third transistor T3 of the second pixel circuit C1-B through the sixth connection electrode 656.

The seventh connection electrode 657 may be electrically connected to the reference voltage line 330 and the fourth semiconductor pattern 420 through contact holes. Accordingly, the reference voltage VREF may be applied to the first electrode of the third transistor T3 through the seventh connection electrode 657.

The sixth insulating layer IL6 may be disposed on the fourth conductive layer 600.

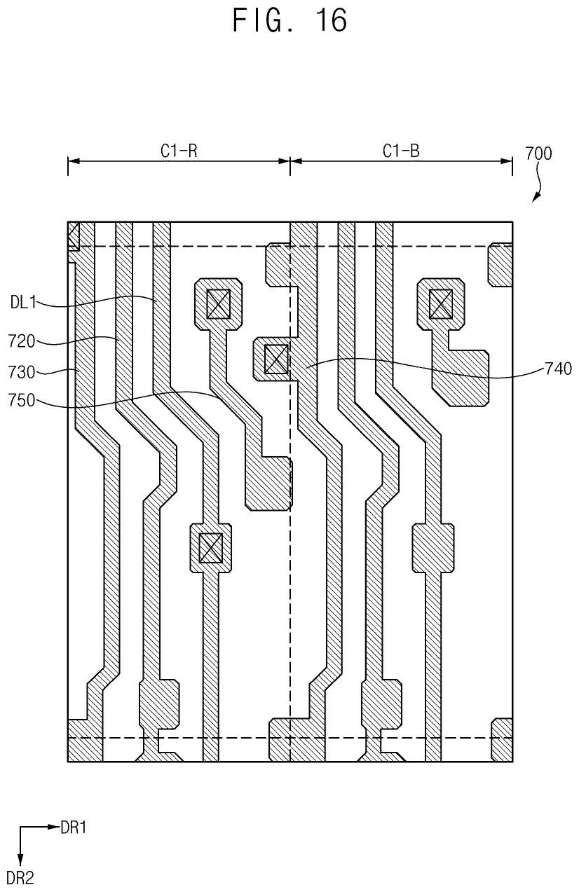

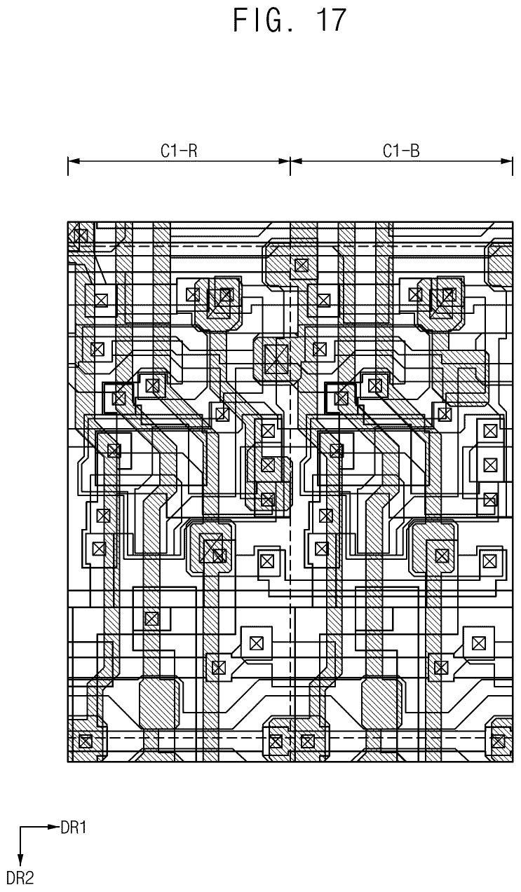

FIG. 16 illustrates the fifth conductive layer 700, and FIG. 17 illustrates the view of FIG. 15 with the fifth conductive layer 700 further disposed.

As illustrated in FIGS. 2 to 4, 16, and 17, the fifth conductive layer 700 may be disposed on the sixth insulating layer IL6. The fifth conductive layer 700 may include a conductive material.

In an embodiment, the fifth conductive layer 700 may include the first data line DL1, a vertical transmission line 720, a signal transmission line 730, an adjacent signal transmission line 740, and a pixel connection electrode 750. The first data line DL1, the vertical transmission line 720, the signal transmission line 730, the adjacent signal transmission line 740, and the pixel connection electrode 750 may be spaced apart from each other in a plan view.

In an embodiment, the first data line DL1 may extend generally in the second direction DR2. The first data line DL1 may partially overlap the data connection pattern 640 of FIG. 14 in a plan view. A first portion of the first data line DL1 may overlap the data connection pattern 640 in a plan view. The first portion of the first data line DL1 may contact the data connection pattern 640 through a contact hole. Accordingly, the data voltage VDATA may be applied to the first electrode of the second transistor T2 of the first pixel circuit C1-R through the first data line DL1 and the data connection pattern 640, and the data voltage VDATA may be applied to the first electrode of the second transistor T2 of the second pixel circuit C1-B through the first data line DL1, the data connection pattern 640, the data connection line 260, and the first adjacent data connection pattern.

As illustrated in FIG. 20 and FIG. 22, the first data line DL1 may partially overlap a second adjacent data connection pattern (e.g., a third data connection pattern 640c of FIG. 22), which is disposed to correspond to the third pixel circuit C1-Ga, in a plan view. A second portion of the first data line DL1 may overlap the second adjacent data connection pattern in a plan view. A contact hole may not be formed between the second portion of the first data line DL1 and the second adjacent data connection pattern. That is, the second portion of the first data line DL1 may be electrically disconnected to (or electrically insulated from) the second adjacent data connection pattern. This will be described later with reference to FIGS. 20 to 22.

In an embodiment, the vertical transmission line 720 may extend generally in the second direction DR2. The vertical transmission line 720 may be electrically connected to the corresponding horizontal transmission line 630 to transmit various signals and/or voltages.

The signal transmission line 730 may extend generally in the second direction DR2. In an embodiment, the signal transmission line 730 may transmit one of the first initialization voltage, the second initialization voltage, the reference voltage VREF, and the driving voltage ELVDD. For example, FIG. 16 illustrates that the signal transmission line 730 disposed to correspond to the first pixel circuit C1-R is electrically connected to the fifth connection electrode 655 through a contact hole and transmits the second initialization voltage, and the adjacent signal transmission line 740 disposed to correspond to the second pixel circuit C1-B is electrically connected to the second driving voltage line 610 through a contact hole and transmits the driving voltage ELVDD, but this is an example and the present disclosure is not limited thereto.

In an embodiment, the pixel connection electrode 750 (e.g., the pixel connection electrode CNE of FIG. 4) may be spaced apart from the first data line DL1 in the first direction DR1. The pixel connection electrode 750 may include a first portion overlapping the fourth connection electrode 654 of FIG. 14 in a plan view and a second portion extending from the first portion. The first portion of the pixel connection electrode 750 may contact the fourth connection electrode 654 through a contact hole.

The seventh insulating layer IL7 may be disposed on the fifth conductive layer 700.

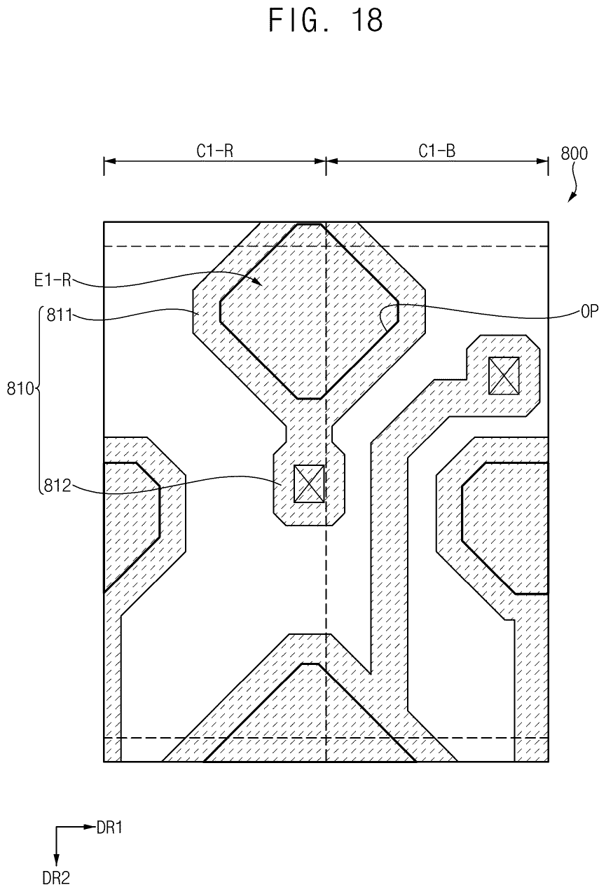

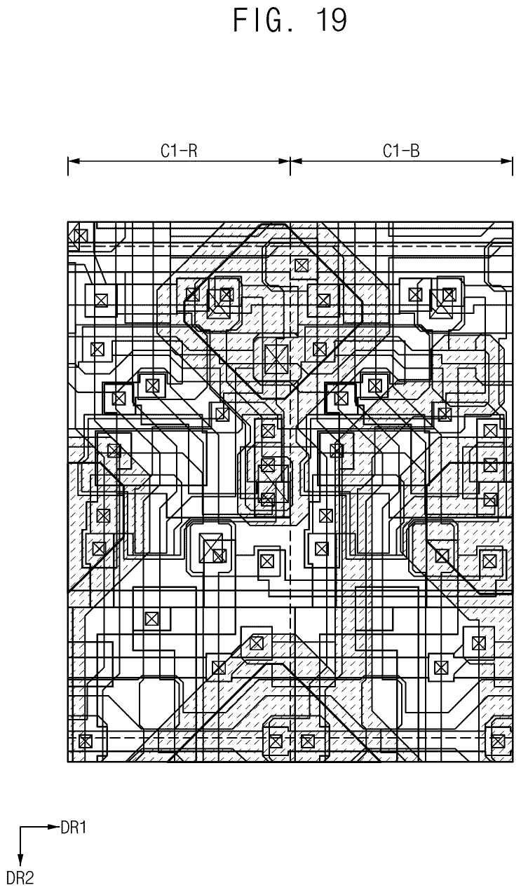

FIG. 18 illustrates the sixth conductive layer 800, and FIG. 19 illustrates the view of FIG. 17 with the sixth conductive layer 800 further disposed.

As illustrated in FIGS. 2 to 4, 18, and 19, the sixth conductive layer 800 may be disposed on the seventh insulating layer IL7. The sixth conductive layer 800 may include a conductive material.

In an embodiment, the sixth conductive layer 800 may include a pixel electrode 810. The pixel electrode 810 may be the pixel electrode of the first light-emitting element E1-R.

The pixel electrode 810 (e.g., the pixel electrode PE of FIG. 4) may include a main portion 811 overlapping the pixel opening OP of the pixel defining layer PDL and a connection portion 812 extending from the main portion 811. The connection portion 812 may not overlap the pixel opening OP in a plan view. The connection portion 812 of the pixel electrode 810 may overlap the second portion of the pixel connection electrode 750 of FIG. 16 in a plan view.

The connection portion 812 of the pixel electrode 810 may contact the second portion of the pixel connection electrode 750 through a contact hole. Accordingly, the first light-emitting element E1-R may be electrically connected to the second electrode of the fourth transistor T4 and the second electrode of the sixth transistor T6 through the pixel connection electrode 750 and the fourth connection electrode 654.

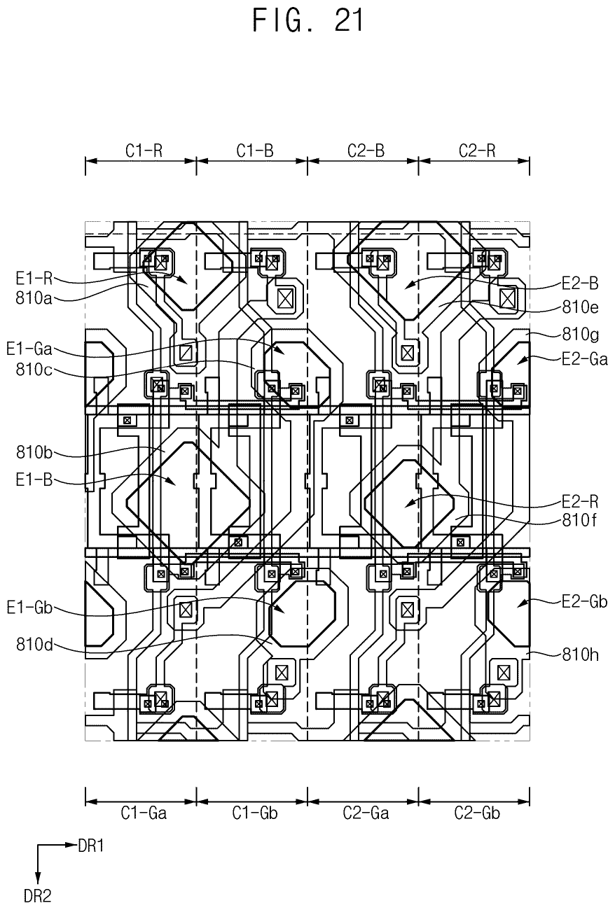

FIGS. 20 and 21 are plan views illustrating first to eighth pixels according to an embodiment. FIG. 22 is an enlarged plan view illustrating area A of FIG. 20.

FIG. 20 illustrates the first to eighth pixel circuits of FIG. 2. For convenience of description, FIG. 20 illustrates some components included in the first to eighth pixel circuits. FIG. 21 illustrates the view of FIG. 2 with the first to eighth light-emitting elements of FIG. 2 further disposed. Hereinafter, with reference to FIGS. 20 to 22, the connection of the first to eighth pixel circuits, the first and second write gate lines GWL1 and GWL2, and the first to fourth data lines DL1, DL2, DL3, and DL4 will be described in more detail.

Referring to FIGS. 2 and 20 to 22, in a plan view, the first pixel circuit C1-R, the second pixel circuit C1-B, the fifth pixel circuit C2-B, and the sixth pixel circuit C2-R disposed in the first pixel row 1R may have the same shape as each other. In a plan view, the third pixel circuit C1-Ga, the fourth pixel circuit C1-Gb, the seventh pixel circuit C2-Ga, and the eighth pixel circuit C2-Gb disposed in the second pixel row 2R may have the same shape as each other.

In the present specification, “the pixel circuits have the same shape as each other” may mean that the transistors and the capacitors included in the pixel circuits have the same shape. For example, as illustrated in FIG. 20, a first pixel connection electrode 750a disposed to correspond to the first pixel circuit C1-R and a second pixel connection electrode 750b disposed to correspond to the second pixel circuit C1-B have different shapes from each other, but the transistors and the capacitors included in the first pixel circuit C1-R (for convenience, only the second transistor T2a and the fourth transistor T4a are illustrated in FIG. 20) and the transistors and the capacitors included in the second pixel circuit C1-B (for convenience, only the second transistor T2b and the fourth transistor T4b are illustrated in FIG. 20) have the same shape, so it can be said that the first pixel circuit C1-R and the second pixel circuit C1-B have the same shape as each other.

In a plan view, the first pixel circuit C1-R disposed in the first pixel row 1R and the third pixel circuit C1-Ga disposed in the second pixel row 2R adjacent to the first pixel row 1R may have shapes that are symmetrical to each other along the second direction DR2 (e.g., vertically flipped shapes in FIG. 20). Similarly, in a plan view, the second pixel circuit C1-B and the fourth pixel circuit C1-Gb may have shapes that are symmetrical to each other along the second direction DR2, the fifth pixel circuit C2-B and the seventh pixel circuit C2-Ga may have shapes that are symmetrical to each other along the second direction DR2, and the sixth pixel circuit C2-R and the eighth pixel circuit C2-Gb may have shapes that are symmetrical to each other along the second direction DR2. Therefore, a size of each of the pixel circuits may be reduced, and the resolution of the display device DD may increase.

In this specification, “the pixel circuits have shapes that are symmetrical to each other along the second direction DR2” may mean that the transistors and the capacitors included in the pixel circuits have shapes that are symmetrical to each other along the second direction DR2. For example, as illustrated in FIG. 20, the second pixel connection electrode 750b disposed to correspond to the second pixel circuit C1-B and a fourth pixel connection electrode 750d disposed to correspond to the fourth pixel circuit C1-Gb have different lengths in the second direction DR2 and do not have completely symmetrical shapes, but the transistors and the capacitors included in the second pixel circuit C1-B (for convenience, only the second transistor T2b and the fourth transistor T4b are illustrated in FIG. 2) and the transistors and the capacitors included in the fourth pixel circuit C1-Gb (for convenience, only the second transistor T2d and the fourth transistor T4d are illustrated in FIG. 2) have shapes that are symmetrical to each other along the second direction DR2, so it can be said that the second pixel circuit C1-B and the fourth pixel circuit C1-Gb have shapes that are symmetrical to each other along the second direction DR2.

In an embodiment, arranging the pixel circuits in symmetrical shapes along the second direction DR2 may reduce systematic variations in wiring parasitics and transistor channel geometries that could otherwise cause spatial luminance variation. By forming the electrical path lengths, overlap areas, and coupling capacitances to be equivalent for pixels of the same color, the symmetry-based layout may maintain consistent drive current characteristics across the display panel DP. This geometric uniformity may be utilized in hybrid 2D/3D displays, where even small variations in pixel performance can result in visible artifacts in the 2D viewing zones.

The first light-emitting element E1-R may be disposed in the first pixel row 1R and the first pixel column 1C. The main portion of the pixel electrode 810a of the first light-emitting element E1-R may be disposed to correspond to the first pixel circuit C1-R. The connection portion of the pixel electrode 810a of the first light-emitting element E1-R may contact the first pixel connection electrode 750a disposed to correspond to the first pixel circuit C1-R through a contact hole. Accordingly, the first light-emitting element E1-R may be electrically connected to the first pixel circuit C1-R.

The second light-emitting element E1-B may be disposed in the second pixel row 2R and the first pixel column 1C. A main portion of a pixel electrode 810b of the second light-emitting element E1-B may be disposed to correspond to the third pixel circuit C1-Ga. A connection portion of the pixel electrode 810b of the second light-emitting element E1-B may contact the second pixel connection electrode 750b disposed to correspond to the second pixel circuit C1-B through a contact hole. Accordingly, the second light-emitting element E1-B may be electrically connected to the second pixel circuit C1-B.

The third light-emitting element E1-Ga may be disposed in the first pixel row 1R and the second pixel column 2C. A main portion of a pixel electrode 810c of the third light-emitting element E1-Ga may be disposed to correspond to the second pixel circuit C1-B. A connection portion of the pixel electrode 810c of the third light-emitting element E1-Ga may contact a third pixel connection electrode 750c disposed to correspond to the third pixel circuit C1-Ga through a contact hole. Accordingly, the third light-emitting element E1-Ga may be electrically connected to the third pixel circuit C1-Ga.

The fourth light-emitting element E1-Gb may be disposed in the second pixel row 2R and the second pixel column 2C. A main portion of a pixel electrode 810d of the fourth light-emitting element E1-Gb may be disposed to correspond to the fourth pixel circuit C1-Gb. A connection portion of the pixel electrode 810d of the fourth light-emitting element E1-Gb may contact the fourth pixel connection electrode 750d disposed to correspond to the fourth pixel circuit C1-Gb through a contact hole. Accordingly, the fourth light-emitting element E1-Gb may be electrically connected to the fourth pixel circuit C1-Gb.

The fifth light-emitting element E2-B may be disposed in the first pixel row 1R and the third pixel column 3C. A main portion of a pixel electrode 810e of the fifth light-emitting element E2-B may be disposed to correspond to the fifth pixel circuit C2-B. A connection portion of the pixel electrode 810e of the fifth light-emitting element E2-B may contact a fifth pixel connection electrode 750e disposed to correspond to the fifth pixel circuit C2-B through a contact hole. Accordingly, the fifth light-emitting element E2-B may be electrically connected to the fifth pixel circuit C2-B.

The sixth light-emitting element E2-R may be disposed in the second pixel row 2R and the third pixel column 3C. A main portion of a pixel electrode 810f of the sixth light-emitting element E2-R may be disposed to correspond to the seventh pixel circuit C2-Ga. A connection portion of the pixel electrode 810f of the sixth light-emitting element E2-R may contact a sixth pixel connection electrode 750f disposed to correspond to the sixth pixel circuit C2-R through a contact hole. Accordingly, the sixth light-emitting element E2-R may be electrically connected to the sixth pixel circuit C2-R.

The seventh light-emitting element E2-Ga may be disposed in the first pixel row 1R and the second pixel column 2C. A main portion of a pixel electrode 810g of the seventh light-emitting element E2-Ga may be disposed to correspond to the sixth pixel circuit C2-R. A connection portion of the pixel electrode 810g of the seventh light-emitting element E2-Ga may contact a seventh pixel connection electrode 750g disposed to correspond to the seventh pixel circuit C2-Ga through a contact hole. Accordingly, the seventh light-emitting element E2-Ga may be electrically connected to the seventh pixel circuit C2-Ga.

The eighth light-emitting element E2-Gb may be disposed in the second pixel row 2R and the second pixel column 2C. A main portion of a pixel electrode 810h of the eighth light-emitting element E2-Gb may be disposed to correspond to the eighth pixel circuit C2-Gb. A connection portion of the pixel electrode 810h of the eighth light-emitting element E2-Gb may contact an eighth pixel connection electrode 750h disposed to correspond to the eighth pixel circuit C2-Gb through a contact hole. Accordingly, the eighth light-emitting element E2-Gb may be electrically connected to the eighth pixel circuit C2-Gb.

Accordingly, the pixel circuits, which are electrically connected to the light-emitting elements that emit light of the same color, may have the same shape as each other in a plan view. For example, as illustrated in FIG. 20, the first pixel circuit C1-R, the sixth pixel circuit C2-R, the ninth pixel circuit C3-R, and the fourteenth pixel circuit C4-R, which are the red pixel circuits, may have the same shape as each other in a plan view. The second pixel circuit C1-B, the fifth pixel circuit C2-B, the tenth pixel circuit C3-B, and the thirteenth pixel circuit C4-B, which are the blue pixel circuits, may have the same shape as each other in a plan view. The third pixel circuit C1-Ga, the fourth pixel circuit C1-Gb, the seventh pixel circuit C2-Ga, the eighth pixel circuit C2-Gb, the eleventh pixel circuit C3-Ga, the twelfth pixel circuit C3-Gb, the fifteenth pixel circuit C4-Ga, and the sixteenth pixel circuit C4-Gb, which are the green pixel circuits, may have the same shape as each other in a plan view. Accordingly, it is possible to prevent a luminance deviation that may occur when pixel circuits electrically connected to light-emitting elements that emit light of the same color have different shapes from each other (e.g., shapes that are symmetrical to each other along the second direction DR2) in a plan view. Accordingly, the display quality of the display device DD may be improved.

Hereinafter, the connection of the first to eighth pixel circuits and the first and second write gate lines GWL1 and GWL2 will be described.

The first write gate line GWL1 may be disposed to correspond to the first pixel row 1R. The first write gate line GWL1 may overlap the first pixel circuit C1-R, the second pixel circuit C1-B, the fifth pixel circuit C2-B, and the sixth pixel circuit C2-R, which are disposed in the first pixel row 1R, in a plan view. The first write gate line GWL1 may be electrically connected to the first pixel circuit C1-R, the third pixel circuit C1-Ga, the fifth pixel circuit C2-B, and the seventh pixel circuit C2-Ga, and may be electrically disconnected to (or electrically insulated from) the second pixel circuit C1-B, the fourth pixel circuit C1-Gb, the sixth pixel circuit C2-R, and the eighth pixel circuit C2-Gb.

The second write gate line GWL2 may be disposed to correspond to the second pixel row 2R. The second write gate line GWL2 may overlap the third pixel circuit C1-Ga, the fourth pixel circuit C1-Gb, the seventh pixel circuit C2-Ga, and the eighth pixel circuit C2-Gb, which are disposed in the second pixel row 2R, in a plan view. The second write gate line GWL2 may be electrically connected to the second pixel circuit C1-B, the fourth pixel circuit C1-Gb, the sixth pixel circuit C2-R, and the eighth pixel circuit C2-Gb, and may be electrically disconnected to (or electrically insulated from) the first pixel circuit C1-R, the third pixel circuit C1-Ga, the fifth pixel circuit C2-B, and the seventh pixel circuit C2-Ga.

A first gate connection line 520a may be disposed to correspond to the first pixel circuit C1-R and the third pixel circuit C1-Ga. The first gate connection line 520a may overlap the first write gate line GWL1 and the second write gate line GWL2 in a plan view. The first gate connection line 520a may include a first portion, which is the gate electrode of the second transistor T2a of the first pixel circuit C1-R, and a second portion, which is the gate electrode of the second transistor T2c of the third pixel circuit C1-Ga.

The first portion of the first write gate line GWL1 may overlap the first portion of the first gate connection line 520a in a plan view. The first portion of the first write gate line GWL1 may contact the first portion of the first gate connection line 520a through a first contact hole CT1. That is, the first gate connection line 520a may be electrically connected to the first write gate line GWL1. Accordingly, the write gate signal may be applied to the gate electrode of the second transistor T2a of the first pixel circuit C1-R and the gate electrode of the second transistor T2c of the third pixel circuit C1-Ga through the first write gate line GWL1.

A first portion of the second write gate line GWL2 may overlap the second portion of the first gate connection line 520a in a plan view. A contact hole may not be formed between the first portion of the second write gate line GWL2 and the second portion of the first gate connection line 520a. That is, the first gate connection line 520a may be electrically disconnected to (or electrically insulated from) the second write gate line GWL2.

The second gate connection line 520b may be disposed to correspond to the second pixel circuit C1-B and the fourth pixel circuit C1-Gb. The second gate connection line 520b may overlap the first write gate line GWL1 and the second write gate line GWL2 in a plan view. The second gate connection line 520b may include a first portion, which is the gate electrode of the second transistor T2b of the second pixel circuit C1-B, and a second portion, which is the gate electrode of the second transistor T2d of the fourth pixel circuit C1-Gb.

The second portion of the first write gate line GWL1 may overlap the first portion of the second gate connection line 520b in a plan view. A contact hole may not be formed between the second portion of the first write gate line GWL1 and the first portion of the second gate connection line 520b. That is, the second gate connection line 520b may be electrically disconnected to (or electrically insulated from) the first write gate line GWL1.

A second portion of the second write gate line GWL2 may overlap the second portion of the second gate connection line 520b in a plan view. The second portion of the second write gate line GWL2 may contact the second portion of the second gate connection line 520b through a second contact hole CT2. That is, the second gate connection line 520b may be electrically connected to the second write gate line GWL2. Accordingly, the write gate signal may be applied to the gate electrode of the second transistor T2b of the second pixel circuit C1-B and the gate electrode of the second transistor T2d of the fourth pixel circuit C1-Gb through the second write gate line GWL2.

Similarly, the third gate connection line 520c may be disposed to correspond to the fifth pixel circuit C2-B and the seventh pixel circuit C2-Ga. The third gate connection line 520c may overlap the first write gate line GWL1 and the second write gate line GWL2 in a plan view. The third gate connection line 520c may be electrically connected to the first write gate line GWL1, and may be electrically disconnected to (or electrically insulated from) the second write gate line GWL2.

The fourth gate connection line 520d may be disposed to correspond to the sixth pixel circuit C2-R and the eighth pixel circuit C2-Gb. The fourth gate connection line 520d may overlap the first write gate line GWL1 and the second write gate line GWL2 in a plan view. The fourth gate connection line 520d may be electrically connected to the second write gate line GWL2, and may be electrically disconnected to (or electrically insulated from) the first write gate line GWL1.

Hereinafter, the connection of the first to eighth pixel circuits and the first to fourth data lines DL1, DL2, DL3, and DL4 will be described.

The first data line DL 1 may be disposed to correspond to the first pixel column 1C. The first data line DL1 may overlap the first pixel circuit C1-R and the third pixel circuit C1-Ga disposed in the first pixel column 1C in a plan view. The first data line DL1 may be electrically connected to the first pixel circuit C1-R and the second pixel circuit C1-B, and may be electrically disconnected to (or electrically insulated from) the third pixel circuit C1-Ga and the fourth pixel circuit C1-Gb.

The second data line DL 2 may be disposed to correspond to the second pixel column 2C. The second data line DL2 may overlap the second pixel circuit C1-B and the fourth pixel circuit C1-Gb disposed in the second pixel column 2C in a plan view. The second data line DL 2 may be electrically connected to the third pixel circuit C1-Ga and the fourth pixel circuit C1-Gb, and may be electrically disconnected to (or electrically insulated from) the first pixel circuit C1-R and the second pixel circuit C1-B.

A first data connection line 260a may be disposed to correspond to the first pixel circuit C1-R and the second pixel circuit C1-B. The first data connection line 260a may include a first portion, which overlaps a first data connection pattern 640a in a plan view, and a second portion, which overlaps a second data connection pattern 640b in a plan view.

The first data connection pattern 640a may be disposed to correspond to the first pixel circuit C1-R, may be electrically connected to the first electrode (a drain area D2a of FIG. 22) of the second transistor T2a of the first pixel circuit C1-R through a third contact hole CT3, and may be electrically connected to the first portion of the first data connection line 260a through a fourth contact hole CT4.

The second data connection pattern 640b may be disposed to correspond to the second pixel circuit C1-B, may be electrically connected to the first electrode (a drain area D2b of FIG. 22) of the second transistor T2b of the second pixel circuit C1-B through a fifth contact hole CT5, and may be electrically connected to the second portion of the first data connection line 260a through a sixth contact hole CT6.

A second data connection line 260b may be disposed to correspond to the third pixel circuit C1-Ga and the fourth pixel circuit C1-Gb. The second data connection line 260b may include a first portion, which overlaps the third data connection pattern 640c in a plan view, and a second portion, which overlaps the fourth data connection pattern 640d in a plan view. In an embodiment, in a plan view, the first data connection line 260a and the second data connection line 260b may have shapes that are symmetrical to each other along the second direction DR2.

The third data connection pattern 640c may be disposed to correspond to the third pixel circuit C1-Ga, may be electrically connected to the first electrode (a drain area D2c of FIG. 22) of the second transistor T2c of the third pixel circuit C1-Ga through a seventh contact hole CT7, and may be electrically connected to the first portion of the second data connection line 260b through an eighth contact hole CT8.

The fourth data connection pattern 640d may be disposed to correspond to the fourth pixel circuit C1-Gb, may be electrically connected to the first electrode (a drain area D2d of FIG. 22) of the second transistor T2d of the fourth pixel circuit C1-Gb through a ninth contact hole CT9, and may be electrically connected to the second portion of the second data connection line 260b through a tenth contact hole CT10.

The first data line DL1 may overlap the first data connection pattern 640a and the third data connection pattern 640c in a plan view. The first data line DL1 may include the first portion overlapping the first data connection pattern 640a in a plan view and the second portion overlapping the third data connection pattern 640c in a plan view.

The first portion of the first data line DL1 may contact the first data connection pattern 640a through an eleventh contact hole CT11. That is, the first data line DL1 may be electrically connected to the first data connection pattern 640a. Accordingly, the data voltage VDATA may be applied to the first electrode (the drain area D2a of FIG. 22) of the second transistor T2a of the first pixel circuit C1-R through the first data line DL1 and the first data connection pattern 640a, and the data voltage VDATA may be applied to the first electrode (the drain area D2b of FIG. 22) of the second transistor T2b of the second pixel circuit C1-B through the first data line DL1, the second data connection pattern 640b, the first data connection line 260a, and the second data connection pattern 640b.

A contact hole may not be formed between the second portion of the first data line DL1 and the third data connection pattern 640c. That is, the first data line DL1 may be electrically disconnected to (or electrically insulated from) the second transistor T2c of the third pixel circuit C1-Ga and the second data connection line 260b.

The second data line DL2 may overlap the first data connection line 260a and the second data connection line 260b in a plan view. The second data line DL2 may include a first portion overlapping the second data connection pattern 640b in a plan view and a second portion overlapping the fourth data connection pattern 640d in a plan view.

A contact hole may not be formed between the first portion of the second data line DL2 and the second data connection pattern 640b. That is, the second data line DL2 may be electrically disconnected to (or electrically insulated from) the second transistor T2b of the second pixel circuit C1-B and the first data connection line 260a.

The second portion of the second data line DL2 may contact the fourth data connection pattern 640d through a twelfth contact hole CT12. That is, the second data line DL2 may be electrically connected to the fourth data connection pattern 640d. Accordingly, the data voltage VDATA may be applied to the first electrode (the drain area D2c of FIG. 22) of the second transistor T2c of the third pixel circuit C1-Ga through the second data line DL2, the fourth data connection pattern 640d, the second data connection line 260b, and the third data connection pattern 640c, and the data voltage VDATA may be applied to the first electrode (the drain area D2d of FIG. 22) of the second transistor T2d of the fourth pixel circuit C1-Gb through the second data line DL2 and the fourth data connection pattern 640d.

Similarly, the third data line DL3 may be disposed to correspond to the third pixel column 3C. The fourth data line DL 4 may be disposed to correspond to the fourth pixel column 4C.

The data voltage VDATA may be applied to the first electrode of the second transistor T2e of the fifth pixel circuit C2-B through the third data line DL3 and a fifth data connection pattern 640e, and the data voltage VDATA may be applied to the first electrode of the second transistor T2f of the sixth pixel circuit C2-R through the third data line DL3, the fifth data connection pattern 640e, a third data connection line 260c, and a sixth data connection pattern 640f.

The data voltage VDATA may be applied to the first electrode of the second transistor T2g of the seventh pixel circuit C2-Ga through the fourth data line DL4, an eighth data connection pattern 640h, a fourth data connection line 260d, and a seventh data connection pattern 640g, and the data voltage VDATA may be applied to the first electrode of the second transistor T2h of the eighth pixel circuit C2-Gb through the fourth data line DL4 and the eighth data connection pattern 640h.

According to embodiments, the pixel circuits, which are electrically connected to the light-emitting elements that emit light of the same color, may have the same shape as each other in a plan view. For example, as illustrated in FIG. 20, the first pixel circuit C1-R, the sixth pixel circuit C2-R, the ninth pixel circuit C3-R, and the fourteenth pixel circuit C4-R, which are the red pixel circuits, may have the same shape as each other in a plan view. The second pixel circuit C1-B, the fifth pixel circuit C2-B, the tenth pixel circuit C3-B, and the thirteenth pixel circuit C4-B, which are the blue pixel circuits, may have the same shape as each other in a plan view. The third pixel circuit C1-Ga, the fourth pixel circuit C1-Gb, the seventh pixel circuit C2-Ga, the eighth pixel circuit C2-Gb, the eleventh pixel circuit C3-Ga, the twelfth pixel circuit C3-Gb, the fifteenth pixel circuit C4-Ga, and the sixteenth pixel circuit C4-Gb, which are the green pixel circuits, may have the same shape as each other in a plan view. Accordingly, it is possible to prevent a luminance deviation that may occur when pixel circuits electrically connected to light-emitting elements that emit light of the same color have different shapes from each other (e.g., shapes that are symmetrical to each other along the second direction DR2) in a plan view. Accordingly, the display quality of the display device DD may be improved.

In addition, all of the pixel circuits, which are electrically connected to some of the data lines DL1 to DL(2M), may be electrically connected to the light-emitting elements that emit light of the same color. That is, some of the data lines DL1 to DL(2M) may be electrically connected only to the red pixel circuits, the blue pixel circuits, or the green pixel circuits. For example, only the green pixel circuits may be electrically connected to each of the second data line DL2 and the fourth data line DL4, and the red pixel circuits and the blue pixel circuits may be electrically disconnected to (or electrically insulated from) each of the second data line DL2 and the fourth data line DL4. Accordingly, the power consumption of the display device DD may be reduced.

In addition, the pixel circuits, which are electrically connected to the same data line, may be electrically connected to different write gate lines. For example, the first pixel circuit C1-R, the second pixel circuit C1-B, the ninth pixel circuit C3-R, and the tenth pixel circuit C3-B may be electrically connected to the first data line DL1, the first pixel circuit C1-R may be electrically connected to the first write gate line GWL1, the second pixel circuit C1-B may be electrically connected to the second write gate line GWL2, the ninth pixel circuit C3-R may be electrically connected to the third write gate line GWL3, and the tenth pixel circuit C3-B may be electrically connected to the fourth write gate line GWL4. Therefore, the operations of the pixel circuits connected to the same data line and the light-emitting elements connected to the pixel circuits may be individually controlled.

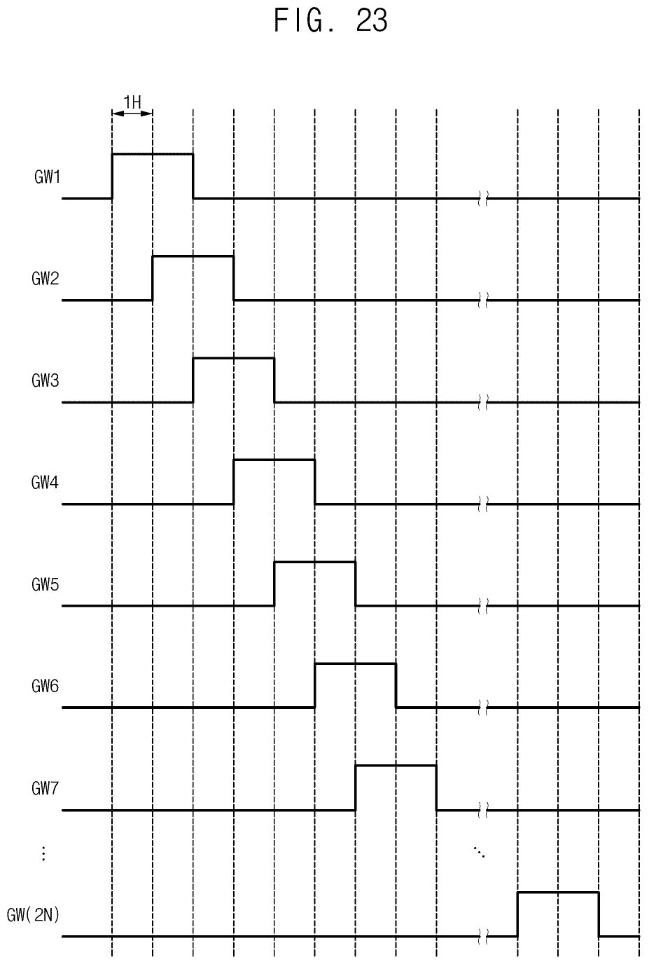

FIGS. 23 to 25 are timing diagrams of write gate signals according to embodiments.

In FIGS. 23 to 25, first to 2N-th write gate signals GW1 to GW(2N) are the write gate signals respectively applied to the first to 2N-th write gate lines GWL1 to GWL(2N) of FIG. 2.

Referring to FIGS. 1, 2, and 23, in an embodiment, on-periods of the write gate signals applied to two adjacent write gate lines may partially overlap each other. For example, the on-period of each of the write gate signals may be maintained for 2H, and the on-periods of the write gate signals applied to two adjacent write gate lines may overlap for 1H. Here, 1H may represent one horizontal period. Accordingly, the on-periods of the write gate signals may increase to reduce crosstalk and low gray-level staining.

An on-period of a 2K−1-th write gate signal applied to a 2K−1-th write gate line may partially overlap an on-period of a 2K-th write gate signal applied to a 2K-th write gate line (K is a positive integer less than or equal to N).

In an embodiment, the gate driver GDR may sequentially output the first to 2N-th write gate signals GW1 to GW(2N) overlapping for 1H to the first to 2N-th write gate lines GWL1 to GWL(2N), respectively.

In an embodiment, partially overlapping the on-periods of write gate signals for adjacent write gate lines may allow more gradual charging of pixel nodes, reducing abrupt potential changes that can lead to crosstalk between neighboring pixels. By extending the on-time to overlap for a portion of the horizontal period (1H), the pixel circuit C may achieve a more stable voltage on the first node N1 before the subsequent pixel row is addressed. This approach may be utilized in, e.g., high-resolution displays, where short addressing times increase the risk of incomplete data writing.

For example, as illustrated in FIG. 23, an on-period of the first write gate signal GW1 may overlap an on-period of the second write gate signal GW2 for 1H. The on-period of the second write gate signal GW2 may overlap an on-period of the third write gate signal GW3 for 1H. The on-period of the third write gate signal GW3 may overlap an on-period of the fourth write gate signal GW4 for 1H. The on-period of the fourth write gate signal GW4 may overlap an on-period of the fifth write gate signal GW5 for 1H. The on-period of the fifth write gate signal GW5 may overlap an on-period of the sixth write gate signal GW6 for 1H. The on-period of the sixth write gate signal GW6 may overlap an on-period of the seventh write gate signal GW7 for 1H. The seventh to twelfth write gate signals GW7-GW12 may be similar to the first to sixth write gate signals GW1-GW6.

Referring to FIGS. 1, 2, 24, and 25, in an embodiment, the on-period of the 2K-1-th write gate signal applied to the 2K−1-th write gate line may not overlap the on-period of the 2K-th write gate signal applied to the 2K-th write gate line (K is a positive integer less than or equal to N). The on-period of the 2K−1-th write gate signal applied to the 2K−1-th write gate line may partially overlap an on-period of a 2K+1-th write gate signal applied to a 2K+1-th write gate line or an on-period of a 2K+2-th write gate signal applied to a 2K+2-th write gate line.

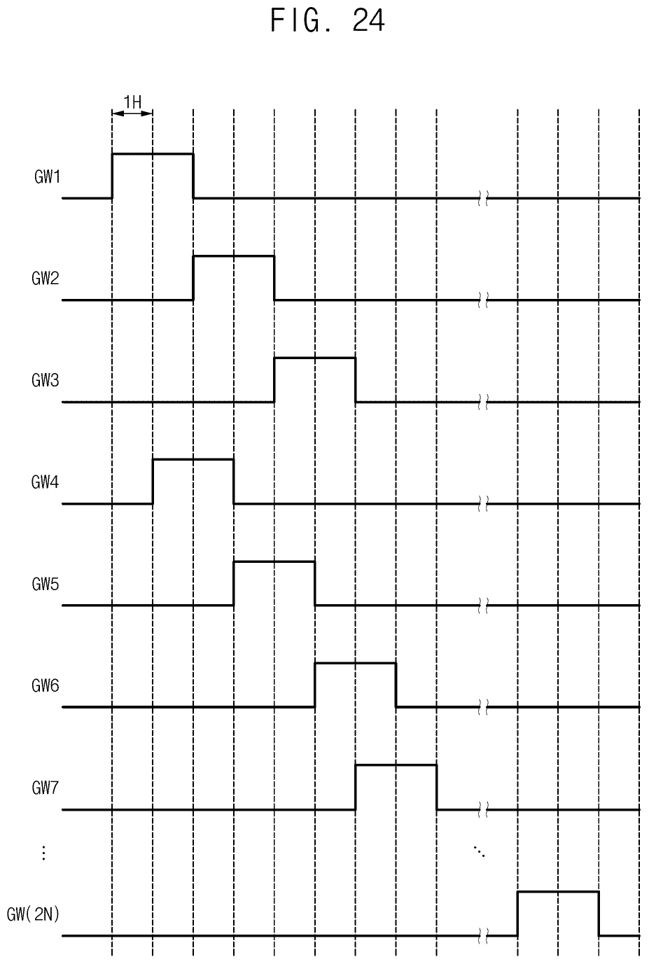

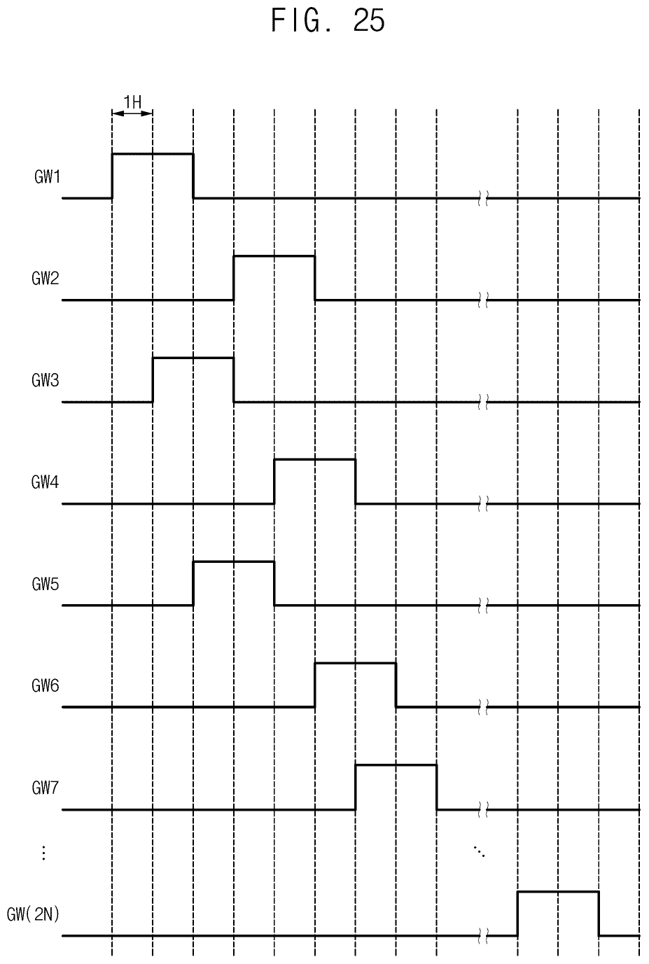

For example, as illustrated in FIGS. 24 and 25, the on-period of the first write gate signal GW1 may not overlap the on-period of the second write gate signal GW2. The on-period of the first write gate signal GW1 may overlap the on-period of the third write gate signal GW3 or the on-period of the fourth write gate signal GW4 for 1H.

The on-period of the third write gate signal GW3 may not overlap the on-period of the fourth write gate signal GW4. The on-period of the third write gate signal GW3 may overlap the on-period of the fifth write gate signal GW5 or the on-period of the sixth write gate signal GW6 for 1H.

The seventh to twelfth write gate signals GW7-GW12 may be similar to the first to sixth write gate signals GW1-GW6.

In an embodiment, as illustrated in FIG. 22, the first write gate signal GW1 may be applied to the first gate connection line 520a through the first write gate line GWL1. The first gate connection line 520a to which the first write gate signal GW1 is applied may overlap the second write gate line GWL2 to which the second write gate signal GW2 is applied in a plan view. The second write gate signal GW2 may be applied to the second gate connection line 520b through the second write gate line GWL 2. The second gate connection line 520b to which the second write gate signal GW2 is applied may overlap the first write gate line GWL1 to which the first write gate signal GW1 is applied in a plan view. In this case, when the on-period of the first write gate signal GW1 partially overlaps the on-period of the second write gate signal GW2, as in embodiment of FIG. 23, a kickback voltage may occur and the display quality of the display device DD may be degraded.

However, according to embodiments of FIGS. 24 and 25, the on-period of the first write gate signal GW1 applied to the first write gate line GWL1 may not overlap the on-period of the second write gate signal GW2 applied to the second write gate line GWL2. Accordingly, even when the first gate connection line 520a to which the first write gate signal GW1 is applied overlaps the second write gate line GWL2 to which the second write gate signal GW2 is applied in a plan view and the second gate connection line 520b to which the second write gate signal GW2 is applied overlaps the first write gate line GWL1 to which the first write gate signal GW1 is applied in a plan view, it is possible to prevent or reduce the degradation of the display quality of the display device DD caused by kickback voltage.

In an embodiment, causing the on-periods of write gate signals for certain adjacent write gate lines to not overlap may further reduce the possibility of kickback voltage when gate connection lines and write gate lines cross in the pixel layout. By preventing or reducing simultaneous transitions in these overlapping regions, the pixel circuit C may avoid abrupt voltage disturbances at sensitive nodes, thereby maintaining the integrity of the stored compensation voltages in capacitors CP1 and CP2. This operational strategy may contribute to improved gray-scale accuracy and stable image quality across the display panel DP.

The display device according to embodiments may be applied to various electronic devices.

FIG. 26 is a block diagram illustrating an electronic device according to an embodiment.

Referring to FIG. 26, an electronic device 10 according to an embodiment may include a display module 11, a processor 12, a memory 13, and a power module 14.

In an embodiment, the electronic device 10 may include the display device (e.g., the display device DD of FIG. 1) according to embodiments described above. In an embodiment, the display module 11 may be included in the display device. The electronic device 10 may further include modules or devices with additional functions other than the display device.

The processor 12 may include at least one of a central processing unit (CPU), an application processor (AP), a graphic processing unit (GPU), a communication processor (CP), an image signal processor (ISP), and a controller.

In an embodiment, the processor 12 may be configured to provide the input image data and/or the input control signal to the display device.

The memory 13 may store data information necessary for the operation of the processor 12 or the display module 11. When the processor 12 executes the application stored in the memory 13, the input image data IMG and/or the input control signal CONT (see FIG. 1) may be transmitted to the display module 11, and the display module 11 may process the received signal and output image information through a display screen.

The power module 14 may include a power supply module, such as a power adapter or a battery device, and a power conversion module which converts the power supplied by the power supply module to generate power required for the operation of the electronic device 10.

At least one of each component of the electronic device 10 described above may be included in the display device according to embodiments. In addition, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

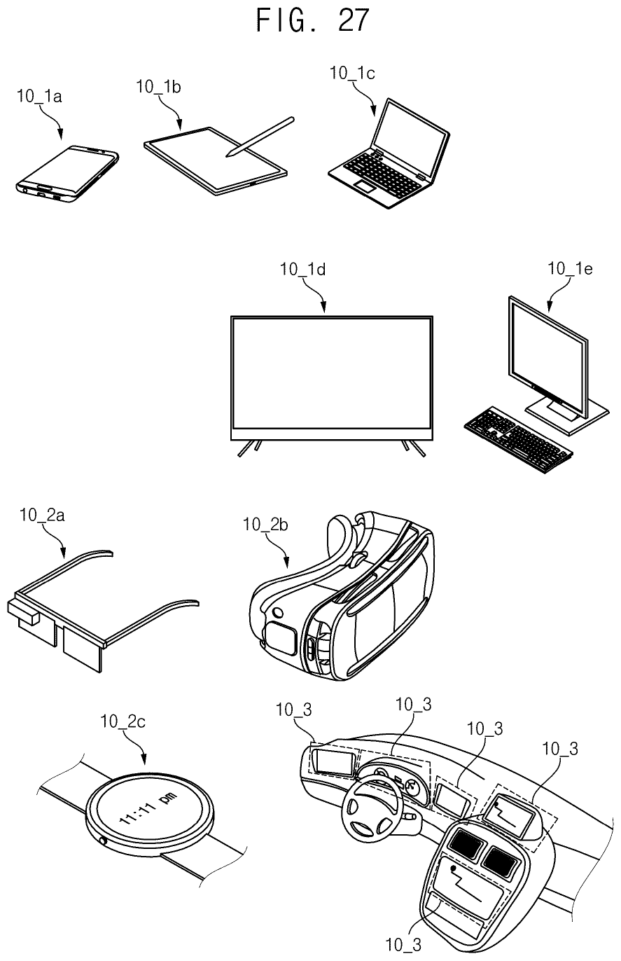

FIG. 27 is a schematic diagram illustrating electronic devices according to various embodiments.

Referring to FIGS. 26 and 27, various electronic devices 10 to which the display device according to embodiments are applied may include not only image display electronic devices such as a smartphone 10_1a, a tablet computer 10_1b, a laptop 10_1c, a TV 10_1d, and a computer monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (“CID”) disposed on a dashboard, and a room mirror display, or the like.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. In an embodiment, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the exemplary embodiments may be physically separated into two or more interacting and discrete blocks, units and/or modules without departing from the scope of the present disclosure. Further, the blocks, units and/or modules of the exemplary embodiments may be physically combined into more complex blocks, units and/or modules without departing from the scope of the present disclosure.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a plurality of pixel circuits disposed in a plurality of pixel rows and a plurality of pixel columns;
a plurality of data lines electrically connected to the pixel circuits and respectively corresponding to the pixel columns; and
a plurality of light-emitting elements respectively electrically connected to the pixel circuits,
wherein the pixel circuits include:
a first pixel circuit disposed in a first pixel row and a first pixel column;
a second pixel circuit disposed in the first pixel row and a second pixel column;
a third pixel circuit disposed in a second pixel row and the first pixel column; and
a fourth pixel circuit disposed in the second pixel row and the second pixel column,
wherein the data lines include:
a first data line corresponding to the first pixel column and electrically connected to the first pixel circuit and the second pixel circuit; and
a second data corresponding to the second pixel column and electrically connected to the third pixel circuit and the fourth pixel circuit.

2. The display device of claim 1, wherein
the first data line overlaps the first pixel circuit and the third pixel circuit in a plan view, and is electrically insulated from the third pixel circuit, and
the second data line overlaps the second pixel circuit and the fourth pixel circuit in the plan view, and is electrically insulated from the second pixel circuit.

3. The display device of claim 1, wherein light-emitting elements that emit light of a same color are respectively electrically connected to all pixel circuits among the plurality of pixel circuits that are electrically connected to the second data line.

4. The display device of claim 1, wherein, in a plan view,
the first pixel circuit and the second pixel circuit have a same shape as each other,
the third pixel circuit and the fourth pixel circuit have a same shape as each other,
the first pixel circuit and the third pixel circuit have shapes that are symmetrical to each other along a column direction, and
the second pixel circuit and the fourth pixel circuit have shapes that are symmetrical to each other along the column direction.

5. The display device of claim 1, wherein
the light-emitting elements are disposed in the pixel rows and the pixel columns, and
the light-emitting elements include:
a first light-emitting element electrically connected to the first pixel circuit and disposed in the first pixel row and the first pixel column;
a second light-emitting element electrically connected to the second pixel circuit and disposed in the second pixel row and the first pixel column;
a third light-emitting element electrically connected to the third pixel circuit and disposed in the first pixel row and the second pixel column; and
a fourth light-emitting element electrically connected to the fourth pixel circuit and disposed in the second pixel row and the second pixel column.

6. The display device of claim 5, wherein the first light-emitting element emits red light, the second light-emitting element emits blue light, and the third light-emitting element and the fourth light-emitting element emit green light.

7. The display device of claim 6,
wherein the pixel circuits further include:
a fifth pixel circuit disposed in the first pixel row and a third pixel column;
a sixth pixel circuit disposed in the first pixel row and a fourth pixel column;
a seventh pixel circuit disposed in the second pixel row and the third pixel column; and
an eighth pixel circuit disposed in the second pixel row and the fourth pixel column,
wherein the data lines further include:
a third data line corresponding to the third pixel column and electrically connected to the fifth pixel circuit and the sixth pixel circuit; and
a fourth data line corresponding to the fourth pixel column and electrically connected to the seventh pixel circuit and the eighth pixel circuit.

8. The display device of claim 7, wherein the light-emitting elements include:
a fifth light-emitting element electrically connected to the fifth pixel circuit and disposed in the first pixel row and the third pixel column;
a sixth light-emitting element electrically connected to the sixth pixel circuit and disposed in the second pixel row and the third pixel column;
a seventh light-emitting element electrically connected to the seventh pixel circuit and disposed in the first pixel row and the fourth pixel column; and
an eighth light-emitting element electrically connected to the eighth pixel circuit and disposed in the second pixel row and the fourth pixel column.

9. The display device of claim 8, wherein the fifth light-emitting element emits blue light, the sixth light-emitting element emits red light, and the seventh light-emitting element and the eighth light-emitting element emit green light.

10. The display device of claim 9, wherein, in a plan view,
the first pixel circuit and the sixth pixel circuit have a same shape as each other, and
the second pixel circuit and the fifth pixel circuit have a same shape as each other.

11. The display device of claim 1, wherein
each of the pixel circuits includes a driving transistor and a write transistor electrically connected to a gate electrode of the driving transistor,
the first data line is electrically connected to a drain electrode of a first write transistor of the first pixel circuit and a drain electrode of a second write transistor of the second pixel circuit, and
the second data line is electrically connected to a drain electrode of a third write transistor of the third pixel circuit and a drain electrode of a fourth write transistor of the fourth pixel circuit.

12. The display device of claim 11, further comprising:
a first data connection line disposed in the first pixel row, extending in a row direction, and electrically connecting the first data line, the drain electrode of the first write transistor, and the drain electrode of the second write transistor; and
a second data connection line disposed in the second pixel row, extending in the row direction, and electrically connecting the second data line, the drain electrode of the third write transistor, and the drain electrode of the fourth write transistor.

13. The display device of claim 12, further comprising:
a first data connection pattern overlapping the first data line and the first data connection line in a plan view;
a second data connection pattern overlapping the second data line and the first data connection line in the plan view;
a third data connection pattern overlapping the first data line and the second data connection line in the plan view; and
a fourth data connection pattern overlapping the second data line and the second data connection line in the plan view,
wherein
the first data line contacts the first data connection line through a first contact hole and is electrically insulated from the second data connection line, and
the second data line contacts the second data connection line through a second contact hole and is electrically insulated from the first data connection line.

14. The display device of claim 13, wherein, in the plan view,
the first data connection pattern and the second data connection pattern have a same shape as each other,
the third data connection pattern and the fourth data connection pattern have a same shape as each other,
the first data connection pattern and the third data connection pattern have shapes that are symmetrical to each other along a column direction, and
the second data connection pattern and the fourth data connection pattern have shapes that are symmetrical to each other along the column direction.

15. The display device of claim 11, further comprising:
a plurality of write gate lines electrically connected to the pixel circuits and respectively corresponding to the pixel rows,
wherein the write gate lines include:
a first write gate line corresponding to the first pixel row and electrically connected to the first pixel circuit and the third pixel circuit; and
a second write gate line corresponding to the second pixel row and electrically connected to the second pixel circuit and the fourth pixel circuit.

16. The display device of claim 15, wherein
the first write gate line overlaps the first pixel circuit and the second pixel circuit in a plan view and is electrically insulated from the second pixel circuit, and
the second write gate line overlaps the third pixel circuit and the fourth pixel circuit in the plan view and is electrically insulated from the third pixel circuit.

17. The display device of claim 15, further comprising:
a first gate connection line disposed in the first pixel column, extending in a column direction, electrically connected to the first write gate line, and including a gate electrode of the first write transistor and a gate electrode of the third write transistor; and
a second gate connection line disposed in the second pixel column, extending in the column direction, electrically connected to the second write gate line, and including a gate electrode of the second write transistor and a gate electrode of the fourth write transistor.

18. The display device of claim 17, wherein
the first gate connection line overlaps the first write gate line and the second write gate line in a plan view, contacts the first write gate line through a third contact hole, and is electrically insulated from the second write gate line, and
the second gate connection line overlaps the first write gate line and the second write gate line in the plan view, contacts the second write gate line through a fourth contact hole, and is electrically insulated from the first write gate line.

19. The display device of claim 18, wherein
the write gate lines further include:
a third write gate line corresponding to a third pixel row; and
a fourth write gate line corresponding to a fourth pixel row,
an on-period of a first write gate signal applied to the first write gate line does not overlap an on-period of a second write gate signal applied to the second write gate line, and
the on-period of the first write gate signal partially overlaps an on-period of a third write gate signal applied to the third write gate line or an on-period of a fourth write gate signal applied to the fourth write gate line.

20. An electronic device, comprising:
a display device configured to display an image; and
a processor configured to transmit input image data and an input control signal to the display device,
wherein the display device includes:
a plurality of pixel circuits disposed in a plurality of pixel rows and a plurality of pixel columns, and including:
a first pixel circuit disposed in a first pixel row and a first pixel column;
a second pixel circuit disposed in the first pixel row and a second pixel column;
a third pixel circuit disposed in a second pixel row and the first pixel column; and
a fourth pixel circuit disposed in the second pixel row and the second pixel column;
a plurality of data lines electrically connected to the pixel circuits, respectively corresponding to the pixel columns, and including:
a first data line corresponding to the first pixel column and electrically connected to the first pixel circuit and the second pixel circuit; and
a second data line corresponding to the second pixel column and electrically connected to the third pixel circuit and the fourth pixel circuit; and
a plurality of light-emitting elements respectively electrically connected to the pixel circuits.
